(19) United States
(12) Patent Application Publication
(10) Pub. No.: US 2025/0098431 A1
(43) Pub. Date: Mar. 20, 2025

(54) DISPLAY DEVICE AND METHOD FOR MANUFACTURING THE SAME

(71) Applicant: Samsung Display Co., Ltd., Yongin-si (KR)

(72) Inventors: WONKYU CHOE, Yongin-si (KR); YOONSEOK KA, Yongin-si (KR); SEHUN KIM, Yongin-si (KR); KYONGSUB KIM, Yongin-si (KR); Jaeyoul KIM, Yongin-si (KR)

(21) Appl. No.: 18/742,773

(22) Filed: Jun. 13, 2024

(30) Foreign Application Priority Data
Sep. 18, 2023 (KR) 10-2023-0124227

(51) Int. Cl. H10K 59/122; H10K 59/12; H10K 59/38; H10K 59/80

(52) U.S. Cl. CPC H10K 59/122; H10K 59/1201; H10K 59/38; H10K 59/8731; H10K 59/8792

(57) ABSTRACT

A display device is provided to include a base layer in which a pixel region and a peripheral region adjacent to the pixel region are defined, a pixel defining film which is provided on the base layer and in which a light emitting opening corresponding to the pixel region is defined, a light emitting element which is provided in the light emitting opening and generates first color light, and an encapsulation layer provided on the light emitting element, wherein the encapsulation layer includes a first inorganic encapsulation layer provided on the light emitting element, a polymer layer which is provided on the first inorganic encapsulation layer and includes a base resin and an organic acid derivative, an organic encapsulation layer provided on the polymer layer, and a second inorganic encapsulation layer provided on the organic encapsulation layer.

### CROSS-REFERENCE TO RELATED APPLICATION

This application claims priority to and the benefit of Korean Patent Application No. 10-2023-0124227, filed on Sep. 18, 2023, in the Korean Intellectual Property Office, the entire content of which is incorporated herein by reference.

### BACKGROUND

### 1. Field

The present disclosure herein relates to a display device and a method for manufacturing the display device.

### 2. Description of the Related Art

Various display devices utilized in multimedia devices such as a television set, a mobile phone, a tablet computer, a navigation unit, a game console, and/or the like are being developed. Such display devices utilize a so-called “self-luminescent” display element which implements display by causing a luminescent material including an organic compound to emit light.

For example, the development of a light emitting element utilizing quantum dots as a light emitting material is underway as an effort to enhance the color reproducibility of display devices. Also, light emitting elements utilizing quantum dots are required (or there is a demand or desire) to incorporate or have increased luminous efficiency and service life.

### SUMMARY

One or more aspects of embodiments of the present disclosure is directed toward a display device having excellent or suitable luminous efficiency by introducing, into an encapsulation layer, a polymer layer including an organic acid derivative.

One or more aspects of embodiments of the present disclosure is directed toward a method for manufacturing the display device, the method being capable of forming an encapsulation layer which may increase current injection characteristics and/or luminous efficiency of a light emitting element.

One or more embodiments of the present disclosure provides a display device including a base layer in which a pixel region and a peripheral region adjacent to the pixel region are defined (e.g., divided), a pixel defining film which is provided on the base layer and in which a light emitting opening corresponding to the pixel region is defined (e.g., divided), a light emitting element which is provided in the light emitting opening and to generate a first color light, and an encapsulation layer provided on the light emitting element, wherein the encapsulation layer includes a first inorganic encapsulation layer provided on the light emitting element, a polymer layer which is provided on the first inorganic encapsulation layer and includes a base resin and an organic acid derivative, an organic encapsulation layer provided on the polymer layer, and a second inorganic encapsulation layer provided on the organic encapsulation layer.

In one or more embodiments, the base resin may include at least one of polyacrylic acid, polymethyl methacrylate, polystyrene, or polyvinyl pyrrolidone.

In one or more embodiments, the organic acid derivative may include a carboxylic acid compound or a carboxylic acid ester compound.

In one or more embodiments, the organic acid derivative may include at least one of citric acid, methacrylic acid, acrylic acid, isobutyric acid, alkyl (meth)acrylate, or hydroxyalkyl (meth)acrylate.

In one or more embodiments, the polymer layer may have a thickness of about 100 nanometer (nm) to about 1,000 nm.

In one or more embodiments, a content (e.g., amount) of the organic acid derivative may be about 2 wt % to about 50 wt % with respect to a total content (e.g., amount) of the polymer layer.

In one or more embodiments, the polymer layer may overlap (e.g., be on) the pixel region and the peripheral region and have a certain thickness.

In one or more embodiments, the polymer layer may be directly provided on the first inorganic encapsulation layer, the organic encapsulation layer may be directly provided on the polymer layer, and the second inorganic encapsulation layer may be directly provided on the organic encapsulation layer.

In one or more embodiments, the light emitting element may include a first electrode, a second electrode, and an emission layer which is provided between the first electrode and the second electrode, and is to emit the first color light, and the first color light may be emitted from the first electrode to the second electrode.

In one or more embodiments, the light emitting element may further include a hole transport region provided between the first electrode and the emission layer, and an electron transport region provided between the second electrode and the emission layer.

In one or more embodiments, the light emitting element may further include an electron transport region provided between the first electrode and the emission layer, and a hole transport region provided between the second electrode and the emission layer.

In one or more embodiments, the emission layer may include quantum dots.

In one or more embodiments, the display device may further include an optical layer provided between the second electrode and the encapsulation layer.

In one or more embodiments, the display device may further include a color filter layer provided on the encapsulation layer, wherein the color filter layer may include a first filter configured to transmit the first color light, a second filter configured to transmit second color light having a wavelength region greater than a wavelength region of the first color light, and a third filter configured to transmit third color light having a wavelength region greater than the wavelength region of the second color light.

In one or more embodiments, the display device may further include a buffer layer provided between the encapsulation layer and the first to third filters, wherein the encapsulation layer may be covered by the buffer layer.

In one or more embodiments, the color filter layer may be directly provided on the encapsulation layer.

In one or more embodiments, the color filter layer may further include light shielding parts provided between a neighboring pair of the first filter, the second filter, and the third filter, and the second inorganic encapsulation layer may be directly provided on a surface (e.g., one surface) of (e.g., each of) the first filter, the second filter, the third filter, and the light shielding parts.

One or more embodiments of the present disclosure provides a method for manufacturing a display device that includes preparing a light emitting element, forming a first inorganic encapsulation layer on the light emitting element, applying a coating solution containing a first base resin and an organic acid derivative on the first inorganic encapsulation layer to form a preliminary polymer layer, drying or heat-treating the preliminary polymer layer at a first temperature to form a polymer layer, forming an organic encapsulation layer on the polymer layer, and forming a second inorganic encapsulation layer on the organic encapsulation layer.

In one or more embodiments, the first temperature may be about 25° C. to about 200° C.

In one or more embodiments, the forming of the organic encapsulation layer may include applying and curing a second base resin on the polymer layer.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure. In the drawings:

FIG. 1 is a perspective view illustrating a display device according to one or more embodiments of the present disclosure;

FIG. 2 is a cross-sectional view of the display device according to one or more embodiments of the present disclosure;

FIG. 3 is a cross-sectional view of a display panel according to one or more embodiments of the present disclosure;

FIG. 4A is a cross-sectional view of a light emitting element according to one or more embodiments of the present disclosure;

FIG. 4B is a cross-sectional view of a light emitting element according to one or more embodiments of the present disclosure;

FIGS. 5A and 5B illustrate enlarged views of some regions each being of a cross-section of the display device according to one or more embodiments of the present disclosure;

FIGS. 6A and 6B illustrate enlarged views of some regions each being of a cross-section of the display device according to one or more embodiments of the present disclosure;

FIG. 7 is a flowchart of a method for manufacturing the display device according to one or more embodiments of the present disclosure; and

FIGS. 8A to 8G are views illustrating some steps (e.g., acts or tasks) of the method for manufacturing a display device according to one or more embodiments of the present disclosure.

### DETAILED DESCRIPTION

The present disclosure may be modified in many alternate forms, and thus specific embodiments will be exemplified in the drawings and described in more detail in the detailed description. It should be understood, however, that it is not intended to limit the present disclosure to the particular forms disclosed, but rather, is intended to cover all modifications, equivalents, and alternatives falling within the spirit and scope of the present disclosure.

In the present specification, when a component (or a region, a layer, a portion, and/or the like) is referred to as being “on,” “connected to,” or “coupled to” another component, it refers to that the component may be directly provided on/connected to/coupled to the other component, or that a third component may be provided therebetween.

When explaining each of drawings, like reference numerals refer to like components throughout, for referring to like elements, and duplicative descriptions thereof may not be provided. Also, in the drawings, the thicknesses, ratios, and dimensions of the components are exaggerated for effective description of technical contents.

As utilized herein, the terms “use,” “using,” and “used” may be considered synonymous with the terms “utilize,” “utilizing,” and “utilized,” respectively.

As utilized herein, expressions such as “at least one of,” “one of,” “selected from,” and “selected from among,” when preceding a list of elements, modify the entire list of elements and do not modify the individual elements of the list. For example, the expressions “at least one of a to c,” “at least one of a, b or c,” and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

The term “and/or” includes all combinations of one or more of which associated configurations may define.

It will be understood that, although the terms “first,” “second,” and/or the like may be utilized herein to describe one or more suitable components, these components should not be limited by these terms. These terms are only utilized to distinguish one component from another. For example, a first component could be termed a second component, and, similarly, a second component could be termed a first component, without departing from the scope of the present disclosure. The terms of a singular forms, “a,” “an,” and “the” are intended to include the plural forms unless the context clearly indicates otherwise.

The terms such as “below,” “under,” “on,” and “above” may be utilized to describe the relationship between components illustrated in the drawings. The terms are utilized as a relative concept and are described with reference to the direction indicated in the drawings. It will be understood that the terms have a relative concept and are described on the basis of the orientation depicted in the drawings. It will be understood that the spatially relative terms are intended to encompass different orientations of the device in use or operation in addition to the orientation depicted in the drawings. For example, if the device in the drawings is turned over, elements described as “beneath” other elements or features would then be oriented “above” or “over” the other elements or features. Thus, the term “beneath” may encompass both an orientation of above and below. The device may be otherwise oriented (rotated 90 degrees or at other orientations), and the spatially relative descriptors used herein should be interpreted accordingly.

It should be understood that the terms “include,” “includes,” “including,” “comprise,” “comprises”, “comprising,” “has,” “having,” and/or “have” are intended to specify the presence of stated features, integers, steps, operations, components, parts, or combinations thereof in the specification, but do not preclude the presence or addition of one or more other features, integers, steps, operations, components, parts, or combinations thereof.

As utilized herein, the term “may” will be understood to refer to “one or more embodiments of the present disclosure,” some of which include the described element and some of which exclude that element and/or include an alternate element. Similarly, alternative language such as “or” refers to “one or more embodiments of the present disclosure,” each including a corresponding listed item.

Unless otherwise defined, all terms (including chemical, technical and scientific terms) utilized herein have the same meaning as commonly understood by one of ordinary skill in the art to which the present disclosure belongs. In some embodiments, it will be understood that terms, such as those defined in commonly utilized dictionaries, should be interpreted as having a meaning that is consistent with their meaning in the context of the relevant art and will not be interpreted in an idealized or overly formal sense unless expressly so defined herein.

As utilized herein, the phrase “consisting essentially of” means that any additional components will not materially affect the chemical, physical, optical, or electrical properties of the semiconductor film.

As utilized herein, the phrase “on a plane,” or “plan view,” refers to viewing a target portion from the top, and the phrase “on a cross-section” means viewing a cross-section formed by vertically cutting a target portion from the side.

In present disclosure, “not include a or any ‘component”, “exclude a or any ‘component”, “component’-free”, and/or the like refers to that the “component” not being added, selected or utilized as a component in the composition/structure, but the “component” of less than a suitable amount may still be included due to other impurities and/or external factor.

Hereinafter, a display device and a method for manufacturing the display device according to one or more embodiments of the present disclosure will be explained with reference to the accompanying drawings.

### Display Device

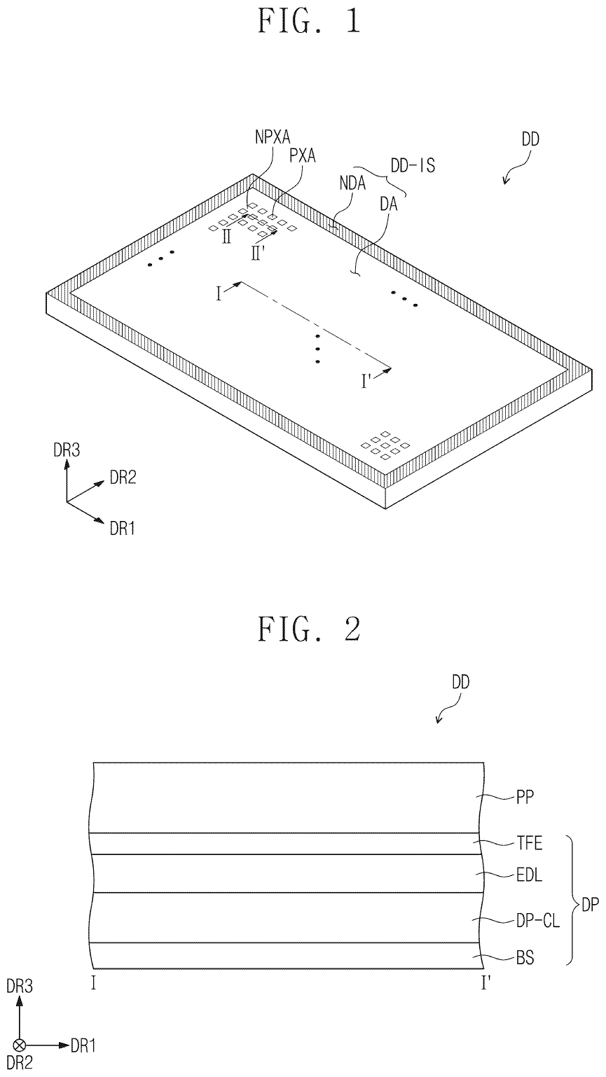

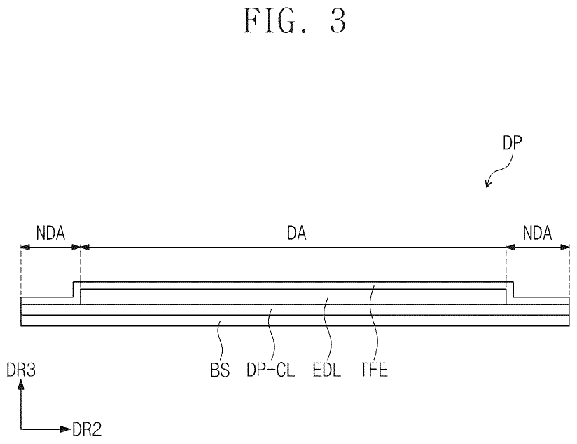

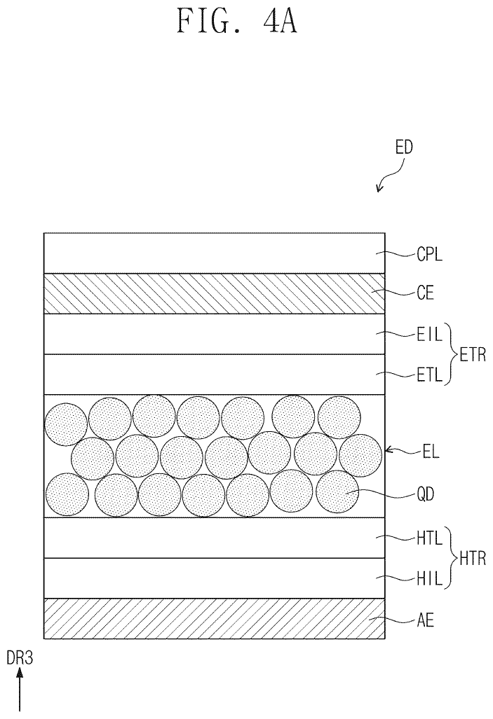

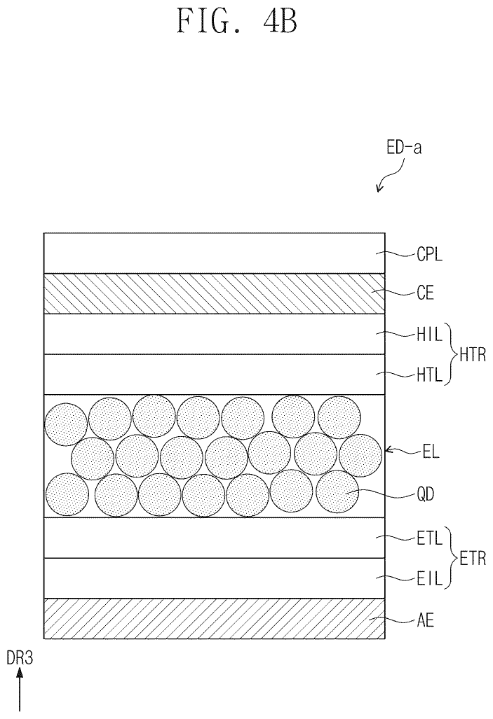

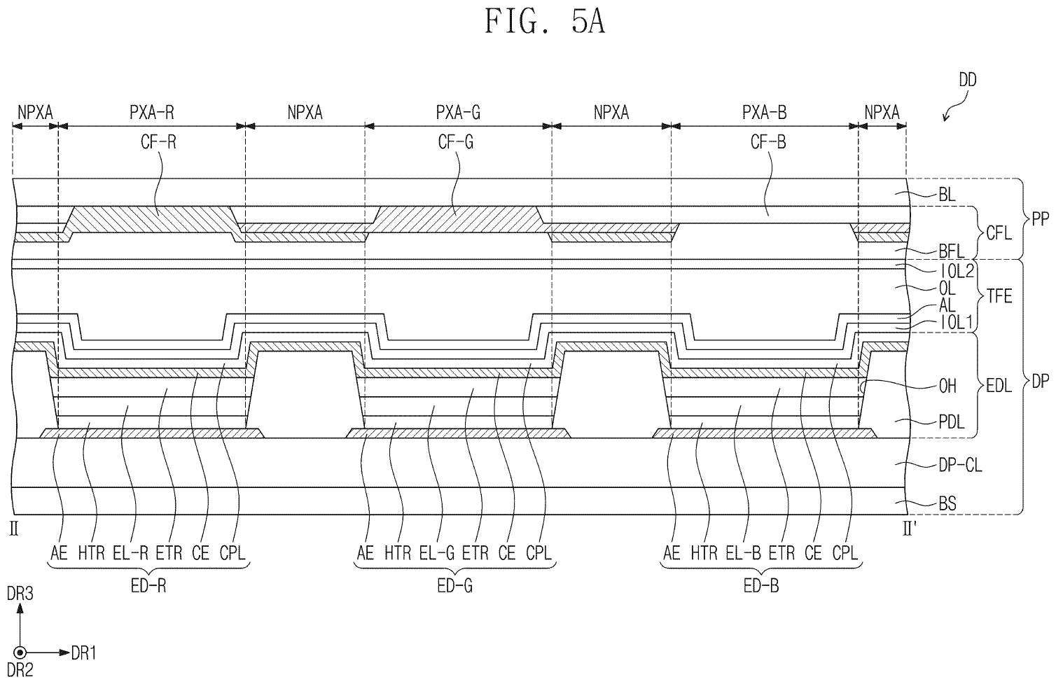

FIG. 1 is a perspective view illustrating a display device according to one or more embodiments of the present disclosure. FIG. 2 is a cross-sectional view of the display device of the embodiment. FIG. 2 illustrates a cross-section taken along line I-I′ shown in FIG. 1. FIG. 3 is a cross-sectional view of a display panel according to one or more embodiments of the present disclosure. FIGS. 4A and 4B are cross sectional views each being of a light emitting element according to one or more embodiments of the present disclosure.

The display device DD of one or more embodiments may be a device that is activated according to an electrical signal. For example, the display device DD may be a large-sized device such as a television, a monitor, an outdoor billboard, and/or the like. In some embodiments, the display device DD may be a small or medium-sized device such as a personal computer, a laptop computer, a personal digital terminal, a car navigation system, a game console, a smart phone, a tablet, or a camera, and/or the like. In some embodiments, the display device in the preceding list are merely presented as an example(s), and thus the display device DD may be adopted for other electronic devices without departing from the present disclosure.

The display device DD may display an image (or a video) through a display surface DD-IS. The display device DD may include a plurality of light emitting regions PXA and peripheral regions NPXA. The display surface DD-IS may be parallel to a plane defined by a first direction DR1 and a second direction DR2. The display surface DD-IS may include a display region DA and a non-display region NDA. The plurality of light emitting regions PXA may be provided in the display region DA. The light emitting regions PXA may be referred to as pixel regions.

The non-display region NDA may be defined (e.g., divided) by the edges of the display surface DD-IS. The non-display region NDA may surround (e.g., be around) the display region DA. However, the embodiment of the present disclosure is not limited thereto, and the non-display region NDA may not be provided, or the non-display region NDA may be provided only in or on one side of the display region DA.

FIG. 1 illustrates the display device DD having the flat display surface DD-IS, but the embodiment of the present disclosure is not limited thereto. The display device DD may include a curved display surface or a three-dimensional display surface. The three-dimensional display surface may include a plurality of display areas indicating different directions.

FIG. 1 and the other drawings illustrate the first direction DR1 to third direction DR3, and the directions indicated by the first to third directions DR1, DR2 and DR3 described in this specification are relative concepts and may be converted into other directions. In the present specification, the first direction DR1 and the second direction DR2 may be orthogonal to each other, and the third direction DR3 may be a normal line direction with respect to a plane defined by the first direction DR1 and the second direction DR2. In the present specification, the “plane” refers to a plane defined by the first direction DR1 and the second direction DR2 (e.g., in a plan view), and a “cross-section” refers to a surface which is perpendicular to the plane defined by the first direction DR1 and the second direction DR2, and parallel to the third direction DR3 (e.g., a cross-sectional view). The display device DD may have a thickness direction parallel to a third direction DR3 that is the normal (e.g., perpendicular) direction with respect to the plane defined by the first direction DR1 and the second direction DR2.

In this specification, a top surface (or a front surface) and a bottom surface (or a rear surface) of each member constituting the display device DD may be defined with respect to the third direction DR3. More specifically, among two surfaces facing each other with respect to the third direction DR3 in one member, a surface relatively adjacent to the display surface DD-IS may be defined as a front surface (or a top surface), and a surface relatively spaced and/or apart from the display surface DD-IS may be defined as a rear surface (or a bottom surface). In some embodiments, in the present specification, the upper portion (or upper side) and the lower portion (or lower side) may be defined with respect to the third direction DR3, and the upper portion (or upper side) may be defined in a direction closer (e.g., proximal) to the display surface DD-IS, and the lower portion (or lower side) may be defined in a direction away (e.g., distal) from the display surface DD-IS.

In the specification, that one component is “directly provided/directly formed” on another component refers to that a third component is not provided between one component and another component. For example, that one component is “directly provided/directly formed” on another component refers to that one component is in “contact” with another component.

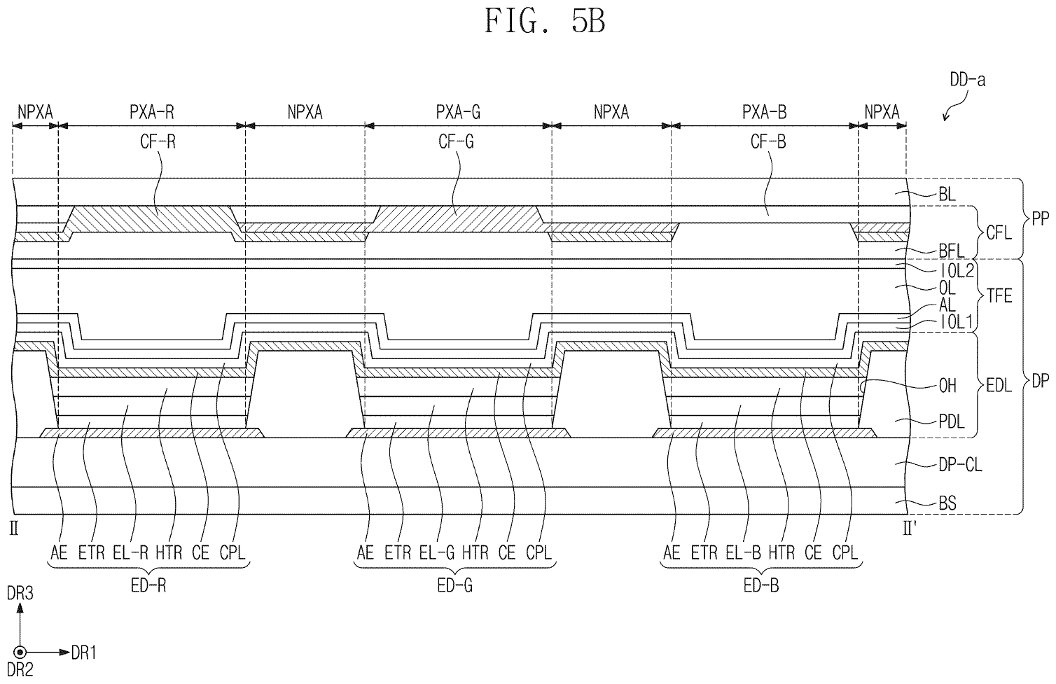

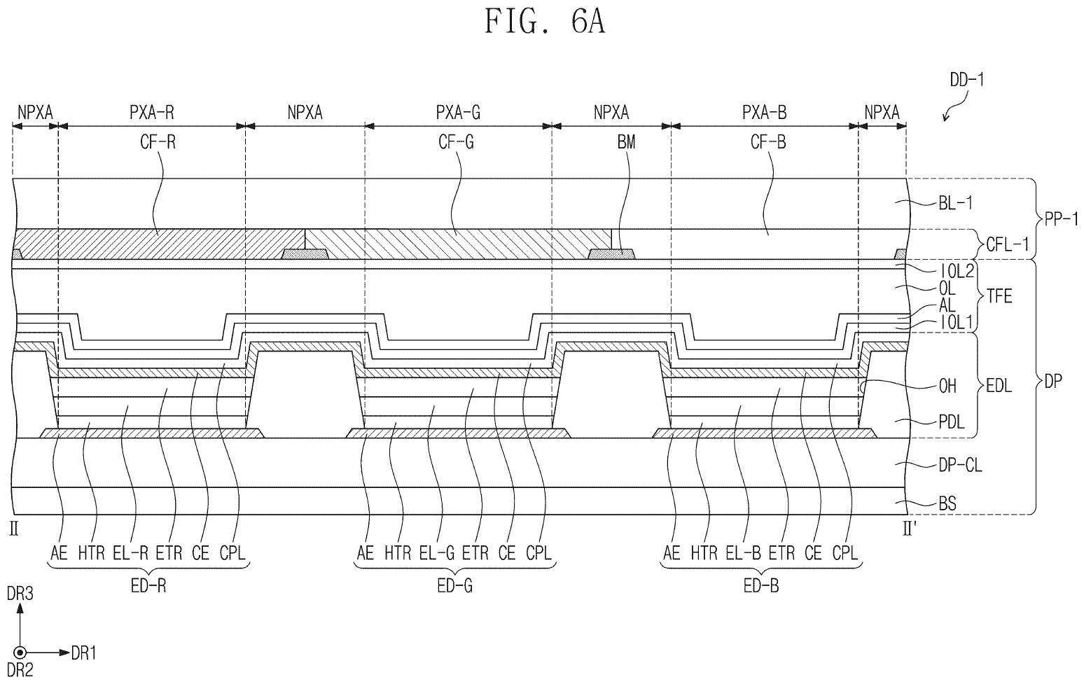

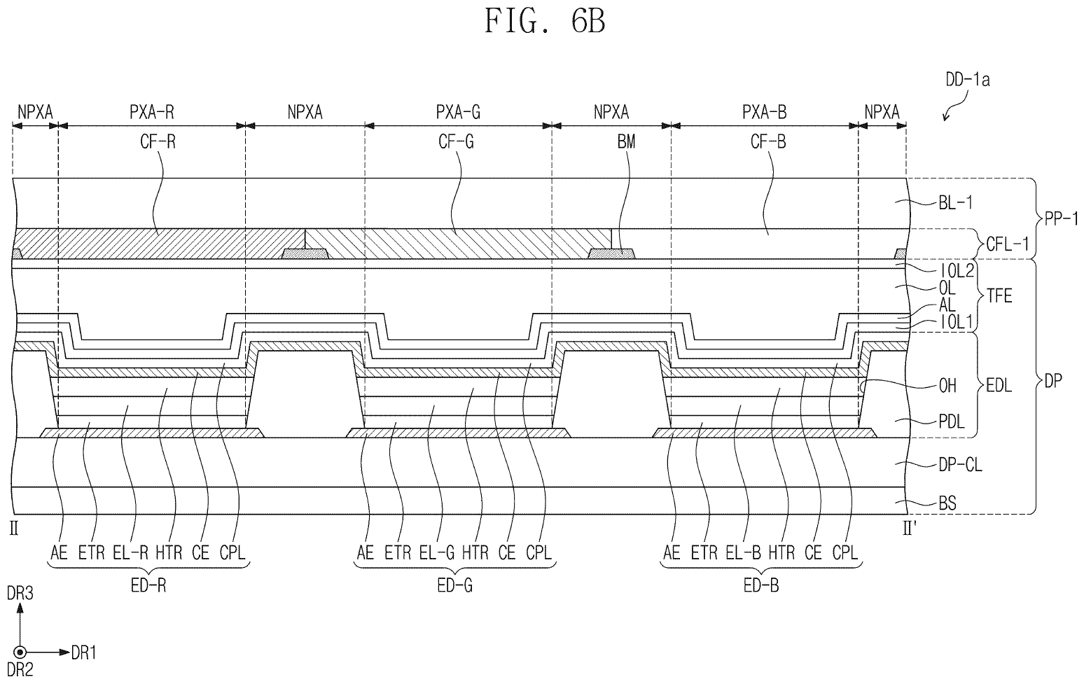

Referring to FIGS. 2 and 3, the display device DD may include a display panel DP and a light control member PP provided on the display panel DP. The display panel DP may include a display layer EDL. The display panel DP may include a base layer BS, a circuit layer DP-CL provided on the base layer BS, and the display layer EDL provided on the circuit layer DP-CL. The display layer EDL may include light emitting elements ED-R, ED-G, and ED-B, as described in more detail elsewhere herein, e.g., in relation to FIGS. 5A to 6B. In some embodiments, the display panel DP may include an encapsulation layer TFE provided on the display layer EDL. In one or more embodiments, the encapsulation layer TFE may be directly provided on the display layer EDL. However, the embodiment of the present disclosure is not limited thereto, and the encapsulation layer TFE may be coupled to the display layer EDL via an additional member.

The display panel DP may be configured to substantially generate a video. The display panel DP of the display device DD in one or more embodiments may be a light emitting display panel. For example, the display panel DP may be a quantum dot light emitting display panel including a quantum dot light emitting element. However, the embodiment of the present disclosure is not limited thereto.

The display region DA and the non-display region NDA corresponding to the display region DA and the non-display region NDA shown in FIG. 1 may be defined on the display panel DP. In the display panel DP, the display region DA may be defined as a region in which pixels are provided. In the display panel DP, the non-display region NDA is a region in which pixels are not provided, and may be defined as a region in which signal lines supporting an operation of the pixels are provided. In the present specification, the sentence “a region corresponds to a region” refers to “overlapping each other,” and is not limited to having the same area.

The optical member PP may be provided on the display panel DP and control reflected light in the display panel DP due to external light.

FIG. 4A is a view illustrating a light emitting element ED according to one or more embodiments, and referring to FIG. 4A, the light emitting element ED according to one or more embodiments includes a first electrode AE, a second electrode CE facing the first electrode AE, and a plurality of functional layers provided between the first electrode AE and the second electrode CE and having an emission layer EL.

The plurality of functional layers may include a hole transport region HTR provided between the first electrode AE and the emission layer EL, and an electron transport region ETR provided between the emission layer EL and the second electrode CE.

The hole transport region HTR and the electron transport region ETR may each include a plurality of sub functional layers. For example, the hole transport region HTR may include a hole injection layer HIL and a hole transport layer HTL as sub functional layers, and the electron transport region ETR may include an electron injection layer EIL and an electron transport layer ETL as sub functional layers. In some embodiments, the embodiment of the present disclosure is not limited thereto, and the hole transport region HTR may further include an electron blocking layer or a hole buffer layer as a sub functional layer, and the electron transport region ETR may further include a hole blocking layer or an electron buffer layer as a sub functional layer.

In the light emitting element ED according to one or more embodiments, the first electrode AE has conductivity (e.g., is a conductor). The first electrode AE may include or be formed of a metal alloy or a conductive compound. The first electrode AE may be an anode. The first electrode AE may be a pixel electrode.

In the light emitting element ED according to one or more embodiments, the first electrode AE may be a reflective electrode. However, the embodiment of the present disclosure is not limited thereto. For example, the first electrode AE may be a transmissive electrode or a transflective electrode. When the first electrode AE is the transflective electrode or the reflective electrode, the first electrode AE may include Ag, Mg Cu, Al, Pt, Pd, Au, Ni, Nd, Ir, Cr, Li, Ca, LiF/Ca, LiF/AI, Mo, Ti, a compound thereof, and/or a mixture thereof (e.g., a mixture of Ag and Mg). Also, the first electrode EL1 may have a multilayer structure including a reflective layer or a transflective layer formed of the herein-described material, and a transmissive conductive layer formed of indium tin oxide (ITO), indium zinc oxide (IZO), zinc oxide (ZnO), indium tin zinc oxide (ITZO), and/or the like. For example, the first electrode AE may be a multilayer metal film and have a structure in which a metal film of ITO/Ag/ITO is stacked.

The hole transport region HTR is provided on the first electrode AE. The hole transport region HTR may include a hole injection layer HIL, a hole transport layer HTL, and/or the like. In some embodiments, the hole transport region HTR may further include at least one of a hole buffer layer or an electron blocking layer EBL in addition to the hole injection layer HIL and the hole transport layer HTL. The hole buffer layer may compensate a resonance distance according to the wavelength of light emitted from an emission layer EL, and may thus increase luminous efficiency. Materials which may be included in the hole transport region HTR may be utilized as materials included in the hole buffer layer. The electron blocking layer may be a layer playing the role of (e.g., capable of) preventing or reducing the amount of electron injection from the electron transport region ETR to the hole transport region HTR.

The hole transport region HTR may have a single layer formed of a single material, a single layer formed of a plurality of different materials or a multilayer structure including a plurality of layers formed of a plurality of different materials. For example, the hole transport region HTR may have a single-layer structure formed of a plurality of different materials, or a structure in which a hole injection layer HIL/hole transport layer HTL, a hole injection layer HIL/hole transport layer HTL/hole buffer layer, a hole injection layer HIL/hole buffer layer, a hole transport layer HTL/hole buffer layer, and/or a hole injection layer HIL/hole transport layer HTL/electron blocking layer are stacked in order from the first electrode AE, but the embodiment of the present disclosure is not limited thereto.

The hole transport region HTR may be formed utilizing one or more suitable methods such as a vacuum deposition method, a spin coating method, a cast method, a Langmuir-Blodgett (LB) method, an inkjet printing method, a laser printing method, and a laser induced thermal imaging (LITI) method.

The hole injection layer HIL may include, for example, at least one selected from among a phthalocyanine compound such as copper phthalocyanine; N,N-diphenyl-N, N-bis-[4-(phenyl-m-tolyl-amino)-phenyl]-biphenyl-4,4′-diamine (DNTPD), 4,4′,4″-[tris(3-methylphenyl)phenylamino]triphenylamine] (m-MTDATA), 4,4′,4″-tris(N,N-diphenylamino) triphenylamine (TDATA), 4,4′,4″-tris{N,-(2-naphthyl)-N-phenylamino)-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N-di(naphthalene-I-yl)-N,N-diphenyl-benzidine (NPD), triphenylamine-containing polyetherketone (TPAPEK), 4-isopropyl-4′-methyldiphenyliodonium tetrakis(pentafluorophenyl) borate, dipyrazino[2,3-f: 2′,3′-h]quinoxaline-2,3,6,7,10,11-hexacarbonitrile (HAT-CN), and/or the like.

The hole transport layer HTL may include general materials suitable in the art. The hole transport layer HTL may further include, for example, carbazole derivatives such as N-phenyl carbazole and polyvinyl carbazole, fluorene derivatives, N,N-bis(3-methylphenyl)-N,N-diphenyl-[1,1-biphenyl]-4,4′-diamine (TPD), triphenylamine derivatives such as 4,4′,4″-tris(N-carbazolyl)triphenylamine (TCTA), N,N-di(naphthalene-I-yl)-N,N-diphenyl-benzidine (NPD), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), and/or the like.

The hole transport region HTR may have a thickness of about 5 (nanometer) nm to about 1,500 nm, for example, about 10 nm to about 500 nm. The hole injection layer HIL may have a thickness of, for example, about 3 nm to about 100 nm, and the hole transport layer HTL may have a thickness of about 3 nm to about 100 nm. For example, the electron blocking layer may have a thickness of about 1 nm to about 100 nm. When the thicknesses of the hole transport region HTR, the hole injection layer HIL, the hole transport layer HTL, and the electron blocking layer satisfy the herein-described ranges, satisfactory hole transport properties may be achieved without a substantial increase in driving voltage.

The emission layer EL may be provided on the hole transport region HTR. The emission layer EL may include a plurality of quantum dots QD.

The quantum dots QD included in the emission layer EL may be stacked to form a layer. In FIG. 4A, for example, the quantum dots QD having a circular cross-section are arranged to form three layers, but the embodiment of the present disclosure is not limited thereto. For example, the arrangement of the quantum dots QD may vary according to the thickness of the emission layer EL, the shape of the quantum dots QD included in the emission layer EL, and the average diameter of the quantum dots QD. For example, in the emission layer EL, the quantum dots QD may be aligned to be adjacent to each other to form a single layer, or may be aligned to form a plurality of layers such as two or three layers.

In some embodiments, in the light emitting element ED of one or more embodiments, an emission layer EL may include a host and a dopant. In one or more embodiments, the emission layer EL may include a quantum dot QD as a dopant material. In one or more embodiments, the emission layer EL may further include a host material.

In some embodiments, in the light emitting element ED of one or more embodiments, an emission layer EL may be to emit fluorescence. For example, a quantum dot QD may be utilized as a fluorescent dopant material.

The quantum dot refers to a crystal of a semiconductor compound. The quantum dot may be to emit light having one or more suitable emission wavelengths depending on the size of crystal. The quantum dot may be to emit light having one or more suitable emission wavelengths as the elemental ratio in the quantum dot compound is adjusted.

The quantum dot may have a diameter of, for example, about 1 nm to about 10 nm. The quantum dot may be synthesized by a wet chemical process, a metal organic chemical vapor deposition process, a molecular beam epitaxy process, a similar process thereto, and/or the like.

The wet chemical process among the quantum dot production processes is a method quantum dot of manufacturing in which a precursor material is mixed with an organic solvent to grow quantum dot particle crystals. When the quantum dot particle crystals grow, the organic solvent naturally may act as a dispersant coordinated on the surface of the quantum dot crystals and control the growth of the particle crystals. Thus, the wet chemical process may control the growth of quantum dot particles through a process which is more easily performed than vapor deposition methods, such as metal organic chemical vapor deposition (MOCVD) or molecular beam epitaxy (MBE), and which may be performed at lower costs compared to the wet chemical process.

The core of the quantum dot may be selected from among a Group II-VI compound, a Group III-V compound, a Group III-VI compound, a Group I-III-IV compound, a Group IV-VI compound, a Group IV element, a Group IV compound, and a combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof. In some embodiments, the Group II-VI semiconductor compound may further include a Group I metal and/or a Group IV element. The Group I-II-VI compound may be selected from CuSnS or CuZnS, and ZnSnS and/or the like may be selected as the Group II-IV-VI compound. The Group I-II-IV-VI compound may be selected from a quaternary compound selected from the group consisting of Cu₂ZnSnS₂, Cu₂ZnSnS₄, Cu₂ZnSnSe₄, Ag₂ZnSnS₂, and a mixture thereof.

The Group III-VI compound may include a binary compound such as In₂S₃ or In₂Se₃, a ternary compound such as InGaS₃ or InGaSe₃, or any combination thereof.

The Group I-III-VI compound may be selected from a ternary compound selected from the group consisting of AgInS, AgInS₂, CuInS, CuInS₂, AgGaS₂, CuGaS₂ CuGaO₂, AgGaO₂, AgAlO₂, and a mixture thereof, or a quaternary compound such as AgInGaS₂ or CuInGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. In some embodiments, the Group III-V compound may further include a Group II metal. For example, InZnP, and/or the like, may be selected as a Group III-II-V compound.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof.

Examples of the Group II-IV-V compound may include a ternary compound selected from the group consisting of ZnSnP, ZnSnP₂, ZnSnAs₂, ZnGeP₂, ZnGeAs₂, CdSnP₂, CdGeP₂, and a mixture thereof.

The Group IV element may be selected from the group consisting of Si, Ge, and a mixture thereof. The Group IV compound may be a binary compound selected from the group consisting of SiC, SiGe, and a mixture thereof.

Each element included in a polynary (i.e., multi-element) compound such as the binary compound, the ternary compound, or the quaternary compound may be present in a particle with a substantially uniform or non-substantially uniform concentration distribution. For example, the indications of the formulae showing quantum dots refer to the types (kinds) of elements included in the quantum dot compounds, and the elemental ratio in the compound may be different. For example, AgInGaS₂ may refer to AgInₓGa₁₋ₓS₂ (where x is a real number of 0 to 1).

In this case, the binary compound, the ternary compound, or the quaternary compound may be present in a particle with a substantially uniform concentration distribution, or may be present in substantially the same particle with a partially different concentration distribution. In some embodiments, the quantum dot may have a core/shell structure in which one quantum dot surrounds another quantum dot. The core/shell structure may have a concentration gradient in which the concentration of elements in the shell decreases toward the core.

In some embodiments, the quantum dot may have the herein-described core-shell structure including a core containing nanocrystals and a shell around (e.g., surrounding) the core. The shell of the quantum dot may serve as a protective layer to prevent or reduce the chemical deformation of the core so as to maintain semiconductor properties, and/or a charging layer to impart electrophoresis properties to the quantum dot. The shell may be a single layer or a multilayer. An example of the shell of the quantum dot may include a metal or non-metal oxide, a semiconductor compound, or a combination thereof.

For example, examples of the metal or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, or a ternary compound such as MgAl₂O₄, CoFe₂O₄, NiFe₂O₄, and/or CoMn₂O₄, but the embodiment of the present disclosure is not limited thereto.

In some embodiments, the semiconductor compound may be, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like, but the embodiment of the present disclosure is not limited thereto.

The quantum dot may have a full width of half maximum (FWHM) of an emission wavelength spectrum of about 45 nm or less, about 40 nm or less, and more about 30 nm or less, and color purity or color reproducibility may be improved in the herein-described range. In some embodiments, light emitted through such a quantum dot is emitted in all directions, and thus a wide viewing angle may be improved.

In some embodiments, although the form of the quantum dot is not particularly limited as long as it is a form commonly utilized in the art, more specifically, the quantum dot in the form of spherical, pyramidal, multi-arm, or cubic nanoparticles, nanotubes, nanowires, nanofibers, nanoplate particles, and/or the like may be utilized.

As the size of the quantum dot is adjusted or the elemental ratio in the quantum dot compound is adjusted, the quantum dot is possible to control the energy band gap, and thus light in one or more suitable wavelength ranges may be obtained in the quantum dot emission layer. Therefore, the quantum dot as herein-described (utilizing different sizes of quantum dots or different elemental ratios in the quantum dot compound) is utilized, and thus the light emitting element, which emits light in one or more suitable wavelengths, may be implemented.

Referring again to FIG. 4A, in the light emitting element ED of one or more embodiments, an electron transport region ETR is provided on the emission layer EL. The electron transport region ETR may include at least one selected from among a hole blocking layer, an electron transport layer ETL, and an electron injection layer EIL, but the embodiment of the present disclosure is not limited thereto.

The electron transport region ETR may have a single layer formed of a single material, a single layer formed of a plurality of different materials, or a multi-layered structure including a plurality of layers formed of a plurality of different materials.

For example, the electron transport region ETR may have a single layer structure of the electron injection layer EIL or the electron transport layer ETL, and may have a single layer structure formed of an electron injection material and an electron transport material. In some embodiments, the electron transport region ETR may have a single-layered structure formed of a plurality of different materials, or may have a structure in which an electron transport layer ETL/electron injection layer EIL, and/or a hole blocking layer/electron transport layer ETL/electron injection layer EIL are stacked in order from the emission layer EL, but the embodiment of the present disclosure is not limited thereto. The thickness of the electron transport region ETR may be, for example, from about 20 nm to about 150 nm.

The electron transport region ETR may be formed utilizing one or more suitable methods such as a vacuum deposition method, a spin coating method, a cast method, a Langmuir-Blodgett (LB) method, an inkjet printing method, a laser printing method, and a laser induced thermal imaging (LITI) method.

When the electron transport region ETR includes the electron transport layer ETL, the electron transport region ETR may include an anthracene-based compound. However, embodiments are not limited thereto, and the electron transport region may include, for example, at least one selected from among tris(8-hydroxyquinolinato)aluminum (Alq₃), 1,3,5-tri[(3-pyridyl)-phen-3-yl]benzene, 2,4,6-tris(3′-(pyridin-3-yl) biphenyl-3-yl)-1,3,5-triazine, bis[2-(diphenylphosphino)phenyl]ether oxide (DPEPO), 2-(4-(N-phenylbenzoimidazolyl-1-ylphenyl)-9,10-dinaphthylanthracene, 1,3,5-tri (1-phenyl-1H-benzo[d]imidazol-2-yl)phenyl (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate) (Bebq₂), 9,10-di(naphthalene-2-yl) anthracene (ADN), and/or a mixture thereof. The thickness of the electron transport layer ETL may be from about 10 nm to about 100 nm, and may be, for example, from about 15 nm to about 50 nm. When the thickness of the electron transport layer ETL satisfies the herein-described range, satisfactory electron transport properties may be obtained without substantial increase of a driving voltage.

When the electron transport region ETR includes the electron injection layer EIL, the electron transport region ETR may be formed utilizing a metal halide such as at least one selected from among LiF, NaCl, CsF, RbCl, and RbI, a lanthanide metal such as Yb, a metal oxide such as Li₂O and/or BaO, or lithium quinolate (LiQ), and/or the like, but the present disclosure is not limited thereto. The electron injection layer EIL may also be formed of a mixture of an electron transport material and an insulating organometallic salt. For example, the organometallic salt may include metal acetate, metal benzoate, metal acetoacetate, metal acetylacetonate, and/or metal stearate. The thicknesses of the electron injection layer(s) EIL may be about 0.1 nm to about 10 nm, and about 0.3 nm to about 9 nm. When the thickness of the electron injection layer EIL satisfies the herein described range, satisfactory electron injection properties may be obtained without inducing substantial increase of a driving voltage.

The electron transport region ETR may include a hole blocking layer as described herein. The hole blocking layer may include, for example, at least one of 2,9-dimethyl-4,7-diphenyl-1,10-phenanthroline (BCP) or 4,7-diphenyl-1,10-phenanthroline (Bphen), but is not limited thereto.

The second electrode CE is provided on the electron transport region ETR. The second electrode CE may be a common electrode or a negative electrode. The second electrode CE may be a transmissive electrode, a transflective electrode, or a reflective electrode. When the second electrode CE is the transmissive electrode, the second electrode CE may be formed of a transparent metal oxide such as indium tin oxide (ITO), indium zinc oxide (IZO), zinc oxide (ZnO), or indium tin zinc oxide (ITZO).

When the second electrode CE is the transflective electrode or the reflective electrode, the second electrode CE may include at least one selected from among Ag, Mg, Cu, Al, Pt, Pd, Au, Ni, Nd, Ir, Cr, Li, Ca, LiF/Ca, LiF/AI, Mo, Ti, Yb, a compound thereof (for example, AgYb, a compound of AgMg and MgAg depending on the content (e.g., amount) thereof), and/or a mixture thereof (for example, a mixture of Ag and Mg). In some embodiments, the first electrode EL1 may have a multilayer structure including a reflective layer or a transflective layer formed of the herein-described materials, and a transparent conductive layer formed of ITO, IZO, ZnO, ITZO, and/or the like

In one or more embodiments, the second electrode CE may be connected with an auxiliary electrode. When the second electrode CE is connected with the auxiliary electrode, the resistance of the second electrode CE may decrease.

The light emitting element ED may further include an optical layer CPL provided on the second electrode CE. The optical layer CPL may include a multilayer or a single layer.

In one or more embodiments, the optical layer CPL may be an organic layer or an inorganic layer. For example, when the optical layer CPL contains an inorganic material, the inorganic material may include an alkaline metal compound (e.g., LiF), an alkaline earth metal compound (e.g., MgF₂), SiON, SiNₓ, SiO_{y}, and/or the like.

For example, when the optical layer CPL includes an organic material, the organic material may include at least one selected from among α-NPD, NPB, TPD, m-MTDATA, Alq₃, CuPc, N4, N4, N4′, N4′-tetra(biphenyl-4-yl) biphenyl-4,4′-diamine (TPD15), 4,4′,4″-tris(carbazol sol-9-yl)triphenylamine (TCTA), and/or the like, or an epoxy resin, or acrylate such as methacrylate. However, the embodiment of the present disclosure is not limited thereto, and the optical layer CPL may include at least one among Compounds P1 to P5:

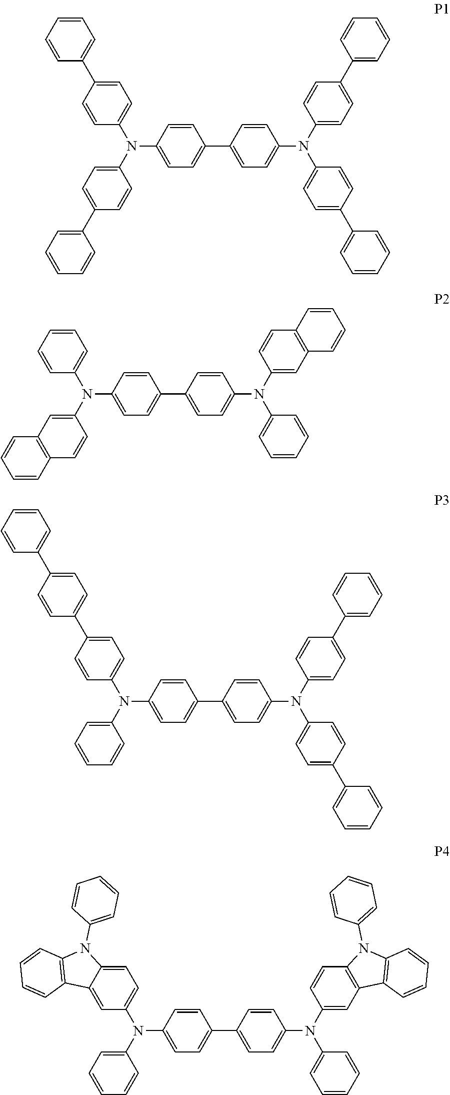

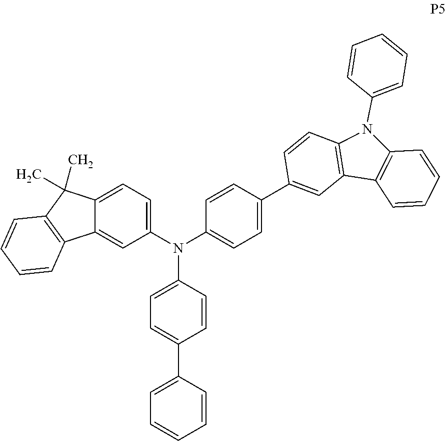 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

In some embodiments, the refractive index of the optical layer CPL may be about 1.6 or more. For example, the refractive index of the optical layer CPL may be about 1.6 or more with respect to light in a wavelength range of about 550 nm to about 660 nm.

FIG. 4B is a cross-sectional view illustrating a light emitting element according to one or more embodiments of the present disclosure. In the description of FIG. 4B, duplicated features which have been described with reference to FIGS. 1 to 4A are not described again, but their differences will be mainly described in more detail.

The light emitting element ED-a illustrated in FIG. 4B is different from the light emitting element ED illustrated in FIG. 4A in the position of the hole transport region HTR and the electron transport region ETR provided. Referring to FIG. 4B, the light emitting element ED-a may include a first electrode AE, an electron transport region ETR provided on the first electrode, an emission layer EL provided on the electron transport region ETR, a hole transport region HTR provided on the emission layer EL, and a second electrode CE provided on the hole transport region HTR. The electron transport region ETR may be provided between the first electrode AE and the emission layer EL, and the hole transport region HTR may be provided between the second electrode CE and the emission layer EL.

FIGS. 5A and 5B illustrate enlarged views of some regions each being of a cross-section of the display device according to the embodiment of the present disclosure. FIGS. 5A and 5B illustrate a cross-section taken along line II-II′ of FIG. 1.

Referring to FIG. 5A, the display device DD of one or more embodiments may include a display panel DP and an optical member PP provided on the display panel DP. The display panel DP may include a base layer BS, a circuit layer DP-CL provided on the base layer BS, and the display layer EDL provided on the circuit layer DP-CL.

Referring to FIGS. 1 and 5A, a plurality of light emitting regions PXA may be provided in the display region DA of the display device DD of one or more embodiments. The plurality of light emitting regions PXA may be regions in which light generated from light emitting elements ED-R, ED-G, and ED-B is emitted, respectively.

The light emitting regions PXA in the display device DD according to one or more embodiments may be arranged in a stripe form. Referring to FIG. 1, the plurality of light emitting regions PXA may be aligned in the first direction DR1 or the second direction DR2. However, the embodiment of the present disclosure is not limited thereto, and the arrangement form of the light emitting regions PXA may be a pentile (PENTILE™) arrangement form or a diamond (Diamond Pixel™) arrangement form, (PENTILET and Diamond Pixel™ are registered trademarks owned by Samsung Display Co., Ltd.).

In some embodiments, FIG. 1 and/or the like illustrates that the areas of the light emitting regions PXA may be similar, but the embodiment of the present disclosure is not limited thereto. For example, the area of the light emitting regions PXA may be different from each other depending on the wavelength region of the emitted light.

The light emitting regions PXA may include first to third light emitting regions PXA-R, PXA-G, and PXA-B. The display device DD may include a plurality of light emitting regions PXA-R, PXA-G, and PXA-B repeatedly provided in the entire display region DA. The display device DD of one or more embodiments may include first to third light emitting regions PXA-R, PXA-G, and PXA-B which are distinguished from each other. In some embodiments, the display device DD may include non-light emitting regions NPXA provided in the periphery of the first to third light emitting regions PXA-R, PXA-G, and PXA-B. The peripheral regions NPXA may define boundaries of the first to third light emitting regions PXA-R, PXA-G, and PXA-B. The peripheral regions NPXA may surround the first to third light emitting regions PXA-R, PXA-G, and PXA-B. A structure for preventing or reducing color mixing between the first to third light emitting regions PXA-R, PXA-G, and PXA-B, for example, a pixel defining film PDL, and/or the like, may be provided in the peripheral regions NPXA.

Each of the first to third light emitting regions PXA-R, PXA-G, and PXA-B may be a region divided by the pixel defining film PDL. The peripheral regions NPXA may be regions between the neighboring pairs of the first to third light emitting regions PXA-R, PXA-G, and PXA-B, which correspond to the pixel defining film PDL.

The first to third light emitting regions PXA-R, PXA-G, and PXA-B may be regions in which light generated from the first to third light emitting elements ED-R, ED-G, and ED-B is emitted, respectively. The first to third light emitting regions PXA-R, PXA-G, and PXA-B may be spaced and/or apart from each other on a plane.

In some embodiments, in the present specification, the first to third light emitting regions PXA-R, PXA-G, and PXA-B may correspond to pixels, respectively. The pixel defining film PDL may separate the first to third light emitting elements ED-R, ED-G, and ED-B. The emission layers EL-R, EL-G and EL-B of the first to third light emitting elements ED-R, ED-G and ED-B may be provided in openings OH defined by the pixel defining film PDL and divided from each other.

The pixel defining film PDL may be formed of a polymer resin. For example, the pixel defining film PDL may include a polyacrylate-based resin or a polyimide-based resin. In some embodiments, the pixel defining film PDL may further include an inorganic material in addition to the polymer resin. In some embodiments, the pixel defining film PDL may include a light absorbing material or a black pigment or a black dye. The pixel defining film PDL including the black pigment or the black dye may implement a black pixel defining film. In forming the pixel defining film PDL, carbon black, and/or the like may be utilized as the black pigment or the black dye, but the embodiment of the present disclosure is not limited thereto.

Also, the pixel defining film PDL may be formed of inorganic materials. For example, the pixel defining film PDL may be formed of inorganic materials such as at least one selected from among silicon nitride (SiNₓ), silicon oxide (SiOₓ) and silicon oxynitride (SiOₓN_{y}), where each of x and y is an integer of 1 or more. For example, each of x and y is an integer of 1 to 4.

The first to third light emitting regions PXA-R, PXA-G, and PXA-B may be divided according to colors of light generated from the first to third light emitting elements ED-R, ED-G, and ED-B, respectively. In the display device DD of one or more embodiments illustrated in FIG. 5A, three light emitting regions PXA-R, PXA-G, and PXA-B, which emit red light, green light, and blue light, respectively, are exemplarily illustrated. For example, in the display device DD of one or more embodiments, the first light emitting region PXA-R may correspond to a red light emitting region, the second light emitting region PXA-G may correspond to a green light emitting region, and the third light emitting region PXA-B may correspond to a blue light emitting region.

The light emitting elements ED-R, ED-G, and ED-B in the display device DD according to one or more embodiments may be to emit light having different wavelength regions. For example, in one or more embodiments, in the display device DD, a first light emitting element ED-R may correspond to a red light emitting element that emits red light, the second light emitting element ED-G may correspond to a green light emitting element that emits green light, and the third light emitting element ED-B may correspond to a blue light emitting element that emits blue light. For example, the red light emitting region PXA-R, the green light emitting region PXA-G, and the blue light emitting region PXA-B of the display device DD may correspond to the first light emitting element ED-R, the second light emitting element ED-G, and the third light emitting element ED-B, respectively.

In some embodiments, FIG. 5A and/or the like illustrates three light emitting regions PXA-R, PXA-G, and PXA-B which are divided from each other, but the embodiment of the present disclosure is not limited thereto, and the display device DD of one or more embodiments may include four or more light emitting regions having different light emitting characteristics.

In the display panel DP, the base layer BS may be a member which provides a base surface on which the display layer EDL is provided. The base layer BS may be a glass substrate, a metal substrate, a plastic substrate, and/or the like. However, the embodiment is not limited thereto, and the base layer BS may be an inorganic layer, an organic layer, and/or a composite material layer.

In one or more embodiments, the circuit layer DP-CL is provided on the base layer BS, and the circuit layer DP-CL may include a plurality of transistors. Each of the transistors may include a control electrode, an input electrode, and an output electrode. For example, the circuit layer DP-CL may include a switching transistor and a driving transistor for driving the light emitting elements ED-R, ED-G, and ED-B of the display layer EDL.

Each of the plurality of light emitting elements ED-R, ED-G, and ED-B of one or more embodiments may include a first electrode AE, a second electrode CE facing the first electrode AE, and emission layers EL-R, EL-G, and EL-B provided between the first electrode AE and the second electrode CE. A hole transport region HTR may be provided between the first electrode AE and each of the emission layers EL-R, EL-G, and EL-B. An electron transport region ETR may be provided between the second electrode CE and each of the emission layers EL-R, EL-G, and EL-B. In one or more embodiments, the plurality of light emitting elements ED-R, ED-G, and ED-B may be to emit light from the first electrode AE to the second electrode CE.

The encapsulation layer TFE may be provided on the display layer EDL. The encapsulation layer TFE may be provided on the light emitting elements ED-R, ED-G, and ED-B. The encapsulation layer TFE may seal the light emitting elements ED-R, ED-G, and ED-B. The encapsulation layer TFE may be provided as a common layer in the entire first to third light emitting regions PXA-R, PXA-G, and PXA-B. The encapsulation layer TFE may be provided as a common layer to overlap the first to third light emitting regions PXA-R, PXA-G, and PXA-B and the peripheral region NPXA. The encapsulation layer TFE may be provided on the second electrode CE. The encapsulation layer TFE may be directly provided on the second electrode CE. In some embodiments, when the display layer EDL of one or more embodiments includes an optical layer CPL, the encapsulation layer TFE may be directly provided on the optical layer CPL. The encapsulation layer TFE may cover the light emitting elements ED-R, ED-G, and ED-B. The encapsulation layer TFE may seal the display layer EDL. The encapsulation layer TFE may be a thin film encapsulation layer.

The encapsulation layer TFE may be formed by stacking a plurality of layers. The encapsulation layer TFE according to one or more embodiments may include at least one organic layer (hereinafter, an organic encapsulation layer) and at least one inorganic layer (hereinafter, an organic encapsulation layer). In some embodiments, the encapsulation layer TFE according to one or more embodiments may include a polymer layer AL provided between the organic encapsulation layer and the inorganic encapsulation layer.

The encapsulation layer TFE may include a first inorganic encapsulation layer IOL1, the polymer layer AL, an organic encapsulation layer OL, and a second inorganic encapsulation layer IOL2. The first inorganic encapsulation layer IOL1, the polymer layer AL, the organic encapsulation layer OL, and the second inorganic encapsulation layer IOL2 may be sequentially provided in the third direction DR3.

The first inorganic encapsulation layer IOL1 may be provided on the second electrode CE. The first inorganic encapsulation layer IOL1 may be directly provided on the second electrode CE. As illustrated in FIG. 5A, when the display panel DP further includes the optical layer CPL, the first inorganic encapsulation layer IOL1 may be provided on the optical layer CPL. The first inorganic encapsulation layer IOL1 may be directly provided on the optical layer CPL. The first inorganic encapsulation layer IOL1 may have a substantially constant thickness on the light emitting elements ED-R, ED-G, and ED-B and the pixel defining film PDL that separates the light emitting elements ED-R, ED-G, and ED-B.

The first inorganic encapsulation layer IOL1 may function to protect the display layer EDL from moisture/oxygen. The first inorganic encapsulation layer IOL1 may include an inorganic material to have a high film density, and may have a large bonding force with a functional layer provided under the first inorganic encapsulation layer IOL1. Accordingly, the interface between the first inorganic encapsulation layer IOL1 and the functional layer provided under the first inorganic encapsulation layer IOL1, such as the optical layer CPL, may be prevented or reduced from permeating moisture and/or oxygen, and peeling of the first inorganic encapsulation layer IOL1 may be prevented or reduced. The first inorganic encapsulation layer IOL1 may include at least one of silicon nitride, silicon oxynitride, silicon oxide, titanium oxide, or aluminum oxide.

The polymer layer AL may be provided on the first inorganic encapsulation layer IOL1. The polymer layer AL may be directly provided on the first inorganic encapsulation layer IOL1. The polymer layer AL may have a substantially constant thickness on the light emitting elements ED-R, ED-G, and ED-B, and the pixel defining film PDL that separates the light emitting elements ED-R, ED-G, and ED-B.

The polymer layer AL may include a first base resin and an organic acid derivative. The polymer layer AL may include an organic acid derivative to improve current efficiency characteristics of the light emitting element and increase the luminous efficiency. The polymer layer AL may be a layer that functions to increase current efficiency and luminous efficiency of the light emitting element including a quantum dot emission layer. The polymer layer AL may be provided on the light emitting elements ED-R, ED-G, and ED-B to improve the stability of the emission layers EL-R, EL-G, and EL-B including quantum dots so that the light emitting elements ED-R, ED-G, and ED-B may exhibit excellent or suitable luminous efficiency.

The polymer layer AL may be a single layer or may have a plurality of layers. When the polymer layer AL has a plurality of layers, the plurality of layers may include the same material or different materials.

The first base resin included in the polymer layer AL may be selected from the group consisting of polyacrylic acid (PAA), poly(methyl methacrylate) (PMMA), poly styrene (PS), poly vinyl pyrrolidone (PVP), poly(dimethylsiloxane) (PDMS), polycarbonate (PC), poly(ethylene terephthalate) (PET), polyethylene (PE), polypropylene (PP), and polyvinyl alcohol (PVA). In one or more embodiments, the first base resin may include at least one of polyacrylic acid (PAA), poly(methyl methacrylate) (PMMA), poly styrene (PS), or poly vinyl pyrrolidone (PVP).

In one or more embodiments, the first base resin may include at least one of polyacrylic acid (PAA), poly(methyl methacrylate) (PMMA), poly styrene (PS), or poly vinyl pyrrolidone (PVP). As the first base resin includes the herein-described material, optical properties and mechanical reliability of the polymer layer AL may be improved, and thin film stability and processability may be improved due to high affinity with the organic acid derivative.

The organic acid derivative may include a carboxylic acid compound or a carboxylic acid ester compound. The polymer layer AL may include one type or kind alone or two or more types (kinds) of organic acid derivatives.

In one or more embodiments, the organic acid derivative may have a pKa of 1.0 or more, and/or a pKa of 3.0 or more. When the pKa value of the organic acid derivative satisfies the herein-described range, the effect of improving the luminous efficiency of the light emitting elements ED-R, ED-G, and ED-B by the polymer layer AL may be increased. In some embodiments, in the present specification, pKa refers to an acid dissociation constant at about 25° C., and when two or more acid dissociation functional groups are included in a molecule, the pKa of the compound may be determined as a value of a functional group having the lowest pKa, that is, a first acid dissociation constant (pKa1).

The carboxylic acid compound may refer to a compound including one or more carboxyl groups in the molecule. The carboxylic acid compound may include at least one selected from among a monocarboxylic acid, a dicarboxylic acid, and a polycarboxylic acid having 1 to 20 or 1 to 10 carbon atoms. For example, the carboxylic acid compound may include formic acid, acetic acid, propionic acid, acrylic acid, methacrylic acid, butyric acid, iso-butyric acid, crotonic acid, valeric acid, iso-valeric acid, citric acid, lactic acid, glycolic acid, oxalic acid, malonic acid, succinic acid, adipic acid, pimelic acid, maleic acid, fumaric acid, tartaric acid, and/or the like.

The carboxylic acid ester compound refers to a compound derived from an ester of an unsaturated carboxylic acid of acrylic acid or methacrylic acid and an alcohol having 1 to 20 carbon atoms. In one or more embodiments, the carboxylic acid ester compound may be an alkyl (meth)acrylate including an alkyl group having 1 to 30, 1 to 20, or 1 to 10 carbon atoms, or a hydroxyalkyl (meth)acrylate including a hydroxyalkyl group having 1 or 2 hydroxyl groups and having 1 to 30, 1 to 20, or 1 to 10 carbon atoms.

Examples of the carboxylic acid ester compound may include at least one selected from among alkyl (meth)acrylates such as methyl (meth)acrylate, ethyl (meth)acrylate, n-propyl (meth)acrylate, i-propyl (meth)acrylate, n-butyl (meth)acrylate, i-butyl (meth)acrylate, sec-butyl (meth)acrylate, t-butyl (meth)acrylate, hexyl (meth)acrylate, 2-ethylhexyl (meth)acrylate, cyclohexyl (meth)acrylate, 2-methoxyethyl (meth)acrylate, and isobornyl (meth)acrylate, and hydroxyalkyl (meth)acrylates such as 2-hydroxyethyl (meth)acrylate, 2-hydroxypropyl (meth)acrylate, 3-hydroxypropyl (meth)acrylate, 3-hydroxybutyl (meth)acrylate, 3-hydroxybutyl (meth)acrylate, and 2-hydroxybutyl (meth)acrylate.

In one or more embodiments, the organic acid derivative may include at least one of citric acid, methacrylic acid, acrylic acid, isobutyl acid, alkyl (meth)acrylate, or hydroxyalkyl (meth)acrylate. In this case, the alkyl (meth)acrylate may be isobornyl (meth)acrylate, and the hydroxyalkyl (meth)acrylate may be 2-hydroxyethyl (meth)acrylate, but the embodiment of the present disclosure is not limited thereto.

In one or more embodiments, the polymer layer AL may have a thickness of about 100 nm to about 1,000 nm. In some embodiments, when the thickness of the polymer layer AL is less than about 100 nm, the function of protecting the emission layer EL is not sufficient, and thus the luminous efficiency is not improved. In some embodiments, when the thickness of the polymer layer AL is greater than about 1,000 nm, light output efficiency may be reduced due to the great thickness, and the mechanical reliability of the thin film may be deteriorated.

The organic encapsulation layer OL may be provided on the polymer layer AL. The organic encapsulation layer OL may be directly provided on the polymer layer AL. The organic encapsulation layer OL may function to protect the display layer EDL from foreign substances such as dust particles. The organic encapsulation layer OL may have a flat top surface. The organic encapsulation layer OL may reduce a stepped portion of the polymer layer AL. The organic encapsulation layer OL may be provided to reduce the stepped portion of the top surface of the polymer layer AL so that the functional layer to be provided thereon may be more substantially uniformly provided. In one or more embodiments, the thickness of the organic encapsulation layer OL may be greater than the thickness of the polymer layer AL. In some embodiments, the thickness of the organic encapsulation layer OL may be greater than the thicknesses of the first and third inorganic encapsulation layers IOL1 and IOL2. For example, the organic encapsulation layer OL may have a thickness of about 1 micrometer (μm) to about 30 μm. However, the embodiment of the present disclosure is not limited thereto.

The organic encapsulation layer OL may include a second base resin. In one or more embodiments, the first base resin included in the polymer layer AL and the second base resin included in the organic encapsulation layer OL may be different from each other. The second base resin may include an acrylic resin, a urethane-based resin, a fluorine-based resin, an epoxy-based resin, a polyester-based resin, a polyamide-based resin, a silicone-based resin, or a combination thereof.

The second inorganic encapsulation layer IOL2 may be provided on the organic encapsulation layer OL. The second inorganic encapsulation layer IOL2 may be directly provided on the organic encapsulation layer OL. In one or more embodiments, the second inorganic encapsulation layer IOL2 may define the uppermost surface of the encapsulation layer TFE.

The second inorganic encapsulation layer IOL2 may function to protect the display layer EDL from moisture and/or oxygen. The second inorganic encapsulation layer IOL2 has a substantially uniform thickness on (e.g., throughout a whole of) the organic encapsulation layer OL, and may have a dense film quality. Accordingly, the second inorganic encapsulation layer IOL2 may have a large bonding force with the organic encapsulation layer OL, and may prevent or reduce moisture and/or oxygen from permeating into the interface between the organic encapsulation layer OL and the second inorganic encapsulation layer IOL2. In one or more embodiments, the second inorganic encapsulation layer IOL2 may include at least one of silicon nitride, silicon oxynitride, silicon oxide, titanium oxide, or aluminum oxide.

In one or more embodiments, the encapsulation layer TFE may further include an additional organic encapsulation layer and an additional inorganic encapsulation layer provided on the second inorganic encapsulation layer IOL2. The encapsulation layer TFE may further include n additional organic encapsulation layers (where n is a natural number of 1 or more) and n additional inorganic encapsulation layers. The n additional organic encapsulation layers and the n additional inorganic encapsulation layers may be alternately provided with each other. On average, the n additional organic encapsulation layers may have a thickness greater than the n additional inorganic encapsulation layers, but the embodiment of the present disclosure is not limited thereto. The description of the organic encapsulation layer OL and the first and second inorganic encapsulation layers IOL1 and IOL2 may be equally applied to the materials of the additional organic encapsulation layer and the additional inorganic encapsulation layer.

The optical member PP may be provided on the display panel DP. The optical member PP may be a reflection reducing layer that reduces reflectance due to external light. For example, the optical member PP may include a polarizing film including a retarder and/or a polarizer, multi-layered reflective layers for destructive interfering with reflected light, or color filters provided corresponding to a pixel arrangement and light emission colors of the display panel DP. When the optical member PP includes color filters, the color filters may be arranged in consideration of emission colors of pixels included in the display panel DP. In one or more embodiments, the optical member PP may not be provided.

In one or more embodiments, the optical member PP may include a base substrate BL and a color filter layer CFL.

The base substrate BL may be a member providing a base surface on which the color filter layer CFL and/or the like is provided. The base substrate BL may be a glass substrate, a metal substrate, a plastic substrate, and/or the like. However, the embodiment is not limited thereto, and the base substrate BL may be an inorganic layer, an organic layer, or a composite material layer.

The color filter layer CFL may include filters CF-R, CF-G, and CF-B. The color filter layer CFL may include first to third filters CF-R, CF-G, and CF-B. The first to third filters CF-R, CF-G, and CF-B may be provided corresponding to the first to third light emitting elements ED-R, ED-G, and ED-B, respectively. For example, the first filter CF-R may be a red filter, the second filter CF-G may be a green filter, and the third filter CF-B may be a blue filter. The first to third filters CF-R, CF-G, and CF-B may be provided corresponding to first to third pixel regions PXA-R, PXA-G, and PXA-B, respectively.

In some embodiments, a plurality of filters CF-R, CF-G, and CF-B, which transmit different light, may be provided to overlap the non-light emitting regions NPXA provided between the neighboring pair of the light emitting regions PXA-R, PXA-G, and PXA-G. The plurality of filters CF-R, CF-G, and CF-B may be provided to overlap each other in the third direction DR3, which is the thickness direction, so that boundaries between adjacent light emitting regions PXA-R, PXA-G, and PXA-B may be distinguished. Accordingly, the light-shielding effect of external light is increased and thus the plurality of filters CF-R, CF-G, and CF-B may have the same function as a black matrix. An overlapping structure of the plurality of filters CF-R, CF-G, and CF-B may have a function of preventing or reducing color mixing.

Each of the first to third filters CF-R, CF-G, and CF-B may include a polymer photosensitive resin, and a pigment or a dye. The first filter CF-R may include a red pigment or a blue dye, the second filter CF-G may include a green pigment or a green dye, and the third filter CF-B may include a blue pigment or a red dye. However, the embodiment of the present disclosure is not limited thereto, and the third filter CF-B may not include (e.g., may exclude) a pigment or dye. The third filter CF-B may include a polymeric photosensitive resin and may not include (e.g., may exclude) a pigment or dye. The third filter CF-B may be transparent. The third filter CF-B may be formed of a transparent photosensitive resin.

The color filter layer CFL may further include a buffer layer BFL. For example, the buffer layer BFL may be a protective layer which protects the first to third filters CF-R, CF-G, and CF-B. The buffer layer BFL may be an inorganic material layer containing at least one inorganic material selected from among silicon nitride, silicon oxide, and silicon oxynitride. The buffer layer BFL may be formed of a single layer or a plurality of layers.

Furthermore, the first filter CF-R and the second filter CF-G may be a yellow filter. The first filter CF-R and the second filter CF-G may not be separated but be provided as one filter.

In one or more embodiments, the color filter layer CFL may further include a light shielding part. The light shielding part may be a black matrix. The light shielding part may include an organic light shielding material or an inorganic light shielding material containing a black pigment or dye. The light shielding part may prevent or reduce light leakage, and may separate boundaries between the adjacent filters CF-R, CF-G, and CF-B.

In some embodiments, unlike the configuration illustrated in FIG. 5A and/or the like, the optical member PP of the display device DD of one or more embodiments may not include (e.g., may exclude) the color filter layer CFL.

In the display device DD of one or more embodiments, the first to third light emitting elements ED-R, ED-G and ED-B each may include the first electrode AE, the hole transport region HTR, the respective emission layers EL-R, EL-G, and EL-B, the electron transport region ETR and the second electrode CE. In some embodiments, each of the light emitting elements ED-R, ED-G and ED-B may include the optical layer CPL provided on the second electrode CE.

The first electrode AE may be exposed in a pixel opening OH of the pixel defining film PDL. The first electrode AE has conductivity (e.g., is a conductor). The first electrode AE may be formed of a metal material, a metal alloy, or a conductive compound. The first electrode AE may be an anode or a cathode. In some embodiments, the first electrode AE may be a pixel electrode. However, the embodiment of the present disclosure is not limited thereto.

The second electrode CE may be provided on the first electrode AE. The second electrode CE may be a cathode or an anode. In one or more embodiments, when the first electrode AE may be an anode, the second electrode CE may be a cathode, and when the first electrode AE is a cathode, the second electrode CE may be an anode. The second electrode CE may be a common electrode. However, the embodiment of the present disclosure is not limited thereto.

A hole transport region HTR may be provided between the first electrode AE and each of the emission layers EL-R, EL-G, and EL-B, and an electron transport region ETR may be provided between each of the emission layers EL-R, EL-G, and EL-B and the second electrode CE.

In one or more embodiments illustrated in FIG. 5A, the hole transport regions HTR, the emission layers EL-R, EL-G, and EL-B, and the electron transport regions ETR of the first to third light emitting elements ED-R, ED-G, and ED-B, respectively, may be provided in the pixel opening OH (e.g., respective ones of the pixel openings OH), and may be separated from the hole transport region HTR, the emission layers EL-R, EL-G, and EL-B, and the electron transport region ETR of the neighboring light emitting regions. For example, in one or more embodiments, the hole transport region HTR, the respective emission layers EL-R, EL-G, and EL-B, and the electron transport region ETR may be patterned and provided in each pixel opening OH.

In the display device DD of one or more embodiments, the hole transport regions HTR, the emission layers EL-R, EL-G, and EL-B, and the electron transport regions ETR of the first to third light emitting elements ED-R, ED-G, and ED-B, respectively, may each be provided and formed by an inkjet printing method according to a method for manufacturing a display device of one or more embodiments, as described in more detail elsewhere herein. However, the embodiment of the present disclosure is not limited thereto. The hole transport region HTR, the emission layers EL-R, EL-G, and EL-B, and the electron transport region ETR may be provided and formed by methods other than the inkjet printing method, and in another embodiment, at least a portion of the hole transport region HTR or the electron transport region ETR may extend to an upper portion of the pixel defining film PDL or at least a portion thereof may be connected to each other.

In the display device DD of one or more embodiments, the second electrode CE and the optical layer CPL may each be provided as a common layer on the entire first to third light emitting elements ED-R, ED-G, and ED-B. However, the embodiment of the present disclosure is not limited thereto, and at least one of the second electrode CE or the optical layer CPL may be provided to be separated from each other in neighboring light emitting regions PXA-R, PXA-G, and PXA-B.

In the display device DD of one or more embodiments, at least one among the first to third light emitting elements ED-R, ED-G, and ED-B may be a quantum dot light emitting element including quantum dots. In one or more embodiments, each of the first to third light emitting elements ED-R, ED-G, and ED-B may be a quantum dot light emitting element including quantum dots. However, the embodiment of the present disclosure is not limited thereto, and at least one selected from the first to third light emitting elements ED-R, ED-G, and ED-B may be a quantum dot light emitting element including quantum dots, and the rest may be organic light emitting elements including organic light emitting materials.

The display device DD-a illustrated in FIG. 5B is different from the display device DD illustrated in FIG. 5A in the position of the hole transport region HTR and the electron transport region ETR provided.

Referring to FIG. 5B, each of the plurality of light emitting elements ED-R, ED-G, and ED-B of one or more embodiments may include a first electrode AE, a second electrode CE facing the first electrode AE, and emission layers EL-R, EL-G, and EL-B provided between the first electrode AE and the second electrode CE. An electron transport region ETR may be provided between the first electrode AE and each of the emission layers EL-R, EL-G, and EL-B. A hole transport region HTR may be provided between the second electrode CE and each of the emission layers EL-R, EL-G, and EL-B. In one or more embodiments, the plurality of light emitting elements ED-R, ED-G, and ED-B may be to emit light from the first electrode AE to the second electrode CE.

FIGS. 6A and 6B illustrate enlarged views of some regions each being of a cross-section of the display device according to the embodiment of the present disclosure; FIGS. 6A and 6B each illustrate a cross-section taken along line II-II′ of FIG. 1.

Referring to FIG. 6A, the display device DD-1 according to one or more embodiments may include a display panel DP and an optical member PP-1 provided on the display panel DP. In the display device DD-1 according to one or more embodiments, the optical member PP-1 may include a color filter layer CFL-1 and a base substrate BL-1, which are sequentially stacked on the encapsulation layer TFE.

The color filter layer CFL-1 may include a plurality of filters CF-R, CF-G, and CF3-B and a light shielding part BM.

Compared with the display device DD illustrated in FIG. 5A, the display device DD-1 according to one or more embodiments illustrated in FIG. 6A is one or more embodiments in which the color filter layer CFL-1 may be provided with the top surface of the encapsulation layer TFE as a base surface. For example, the filters CF-R, CF-G, and CF-B of the color filter layer CFL-1 may be formed on the encapsulation layer TFE by a substantially continuous process. The color filter layer CFL-1 may be formed by utilizing the top surface of the second inorganic encapsulation layer IOL2 included in the encapsulation layer TFE as a base surface, and may have a shape different from that illustrated in FIG. 5A.

In the color filter layer CFL-1 of one or more embodiments, the light shielding part BM may be a black matrix. The light shielding part BM may include an organic light shielding material or an inorganic light shielding material containing a black pigment or dye. The light shielding part BM may prevent or reduce light leakage, and may separate boundaries between the adjacent filters CF-R, CF-G, and CF-B.

The display device DD-1a illustrated in FIG. 6B is different from the display device DD-1 illustrated in FIG. 6A in the position of the hole transport region HTR and the electron transport region ETR provided.

Referring to FIG. 6B, each of the plurality of light emitting elements ED-R, ED-G, and ED-B of one or more embodiments may include a first electrode AE, a second electrode CE facing the first electrode AE, and emission layers EL-R, EL-G, and EL-B provided between the first electrode AE and the second electrode CE. An electron transport region ETR may be provided between the first electrode AE and each of the emission layers EL-R, EL-G, and EL-B. A hole transport region HTR may be provided between the second electrode CE and each of the emission layers EL-R, EL-G, and EL-B. In one or more embodiments, the plurality of light emitting elements ED-R, ED-G, and ED-B may be to emit light from the first electrode AE to the second electrode CE.

In the display devices DD, DD-a, DD-1, and DD-1a of one or more embodiments, the encapsulation layer TFE may include the first inorganic encapsulation layer IOL1, the organic encapsulation layer OL, and the second inorganic encapsulation layer IOL2 sequentially stacked in the thickness direction, and the polymer layer AL which is provided between the first inorganic encapsulation layer IOL1 and the organic encapsulation layer OL and includes an organic acid derivative is included, thereby increasing the current efficiency and luminous efficiency of the light emitting elements ED-R, ED-G, and ED-B including quantum dots. Accordingly, the display devices DD and DD-a including the encapsulation layer TFE of one or more embodiments may exhibit excellent or suitable luminous efficiency.

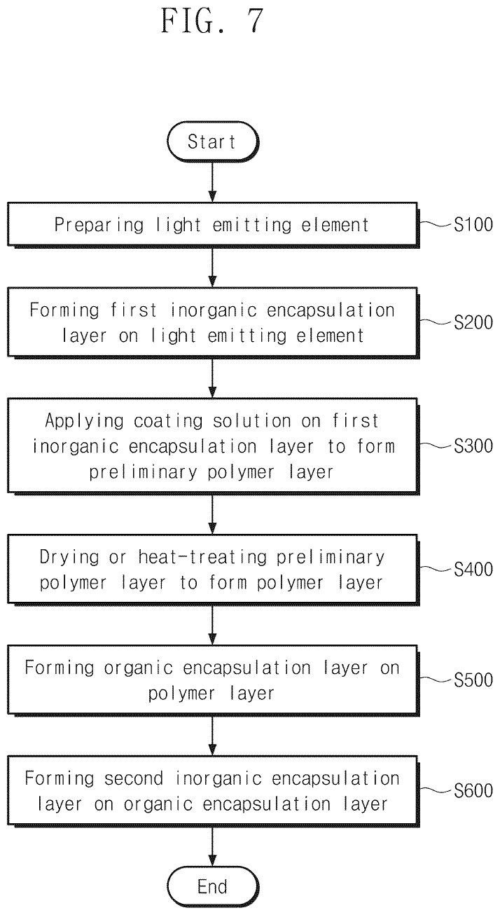

FIG. 7 is a flowchart illustrating a method for manufacturing a display device according to one or more embodiments. Referring to FIG. 7, a method for manufacturing a display device according to one or more embodiments of the present disclosure includes preparing a light emitting element (S100), forming a first inorganic encapsulation layer on the light emitting element (S200), applying a coating solution on the first inorganic encapsulation layer to form a preliminary polymer layer (S300), drying or heat-treating the preliminary polymer layer at a first temperature to form a polymer layer (S400), forming an organic encapsulation layer on the polymer layer (S500), and forming a second inorganic encapsulation layer on the organic encapsulation layer (S600).

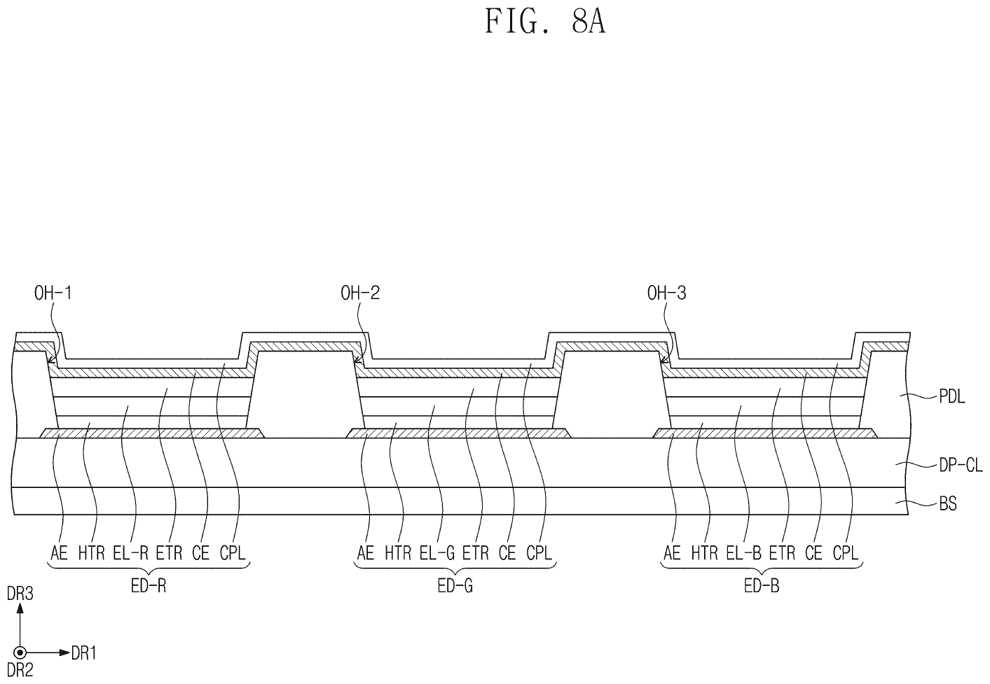

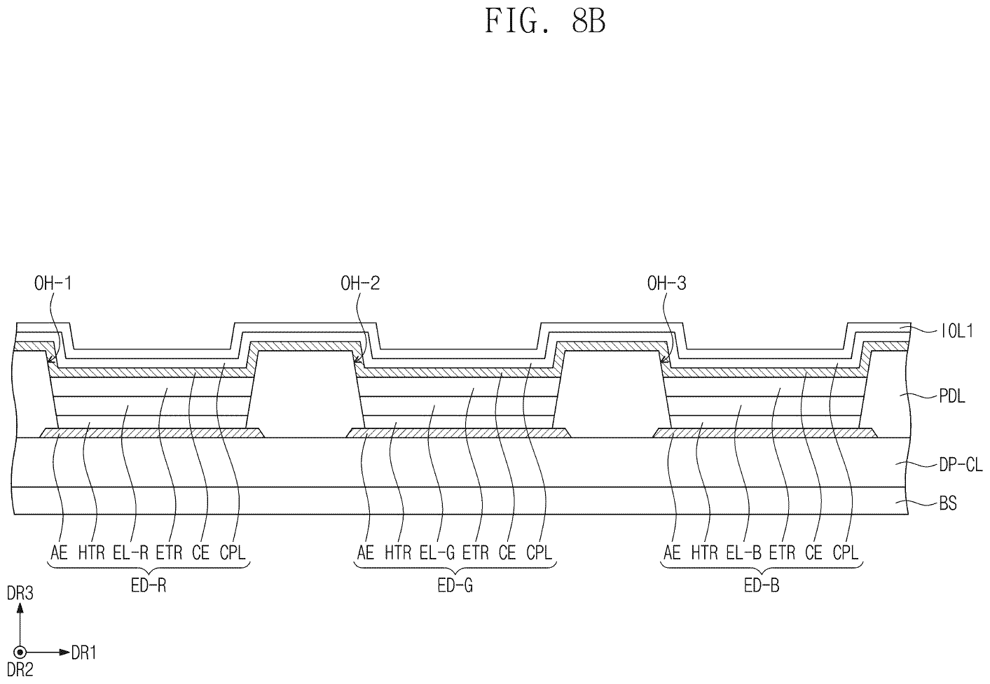

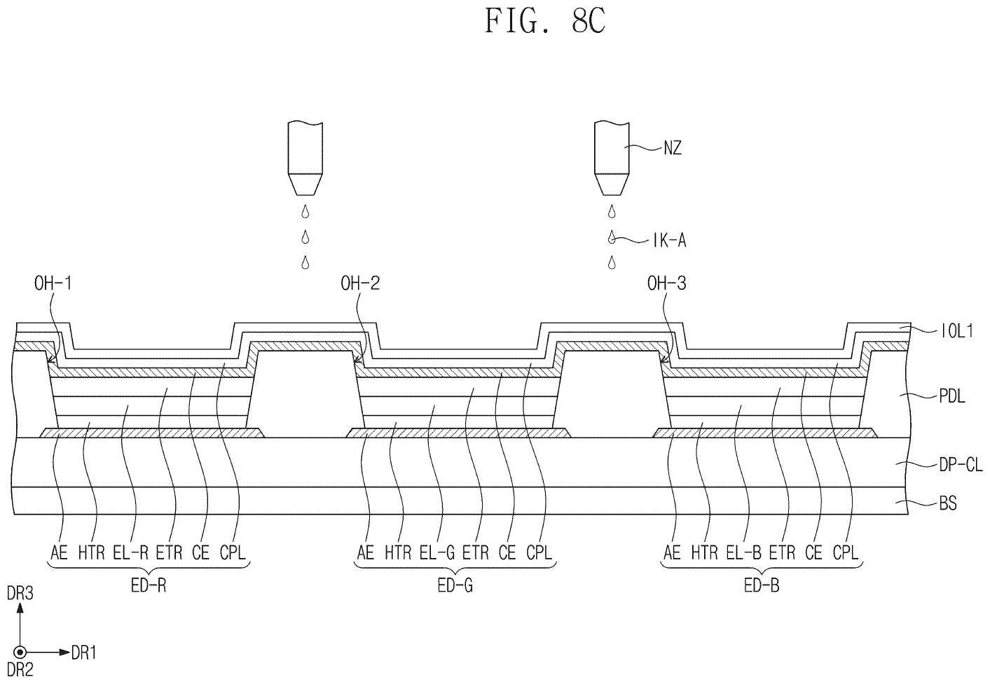

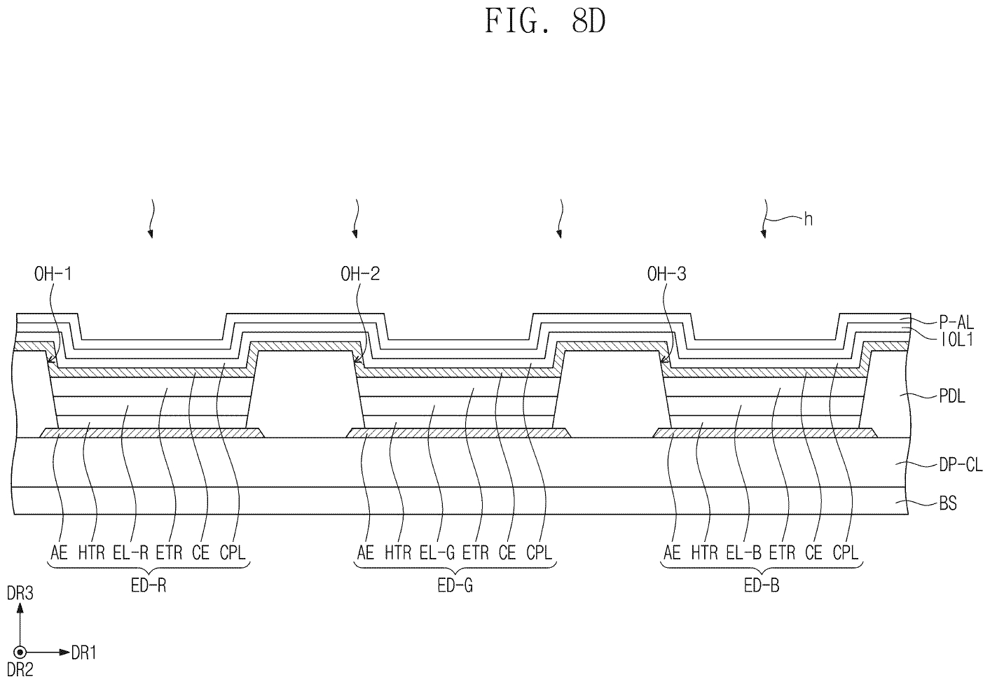

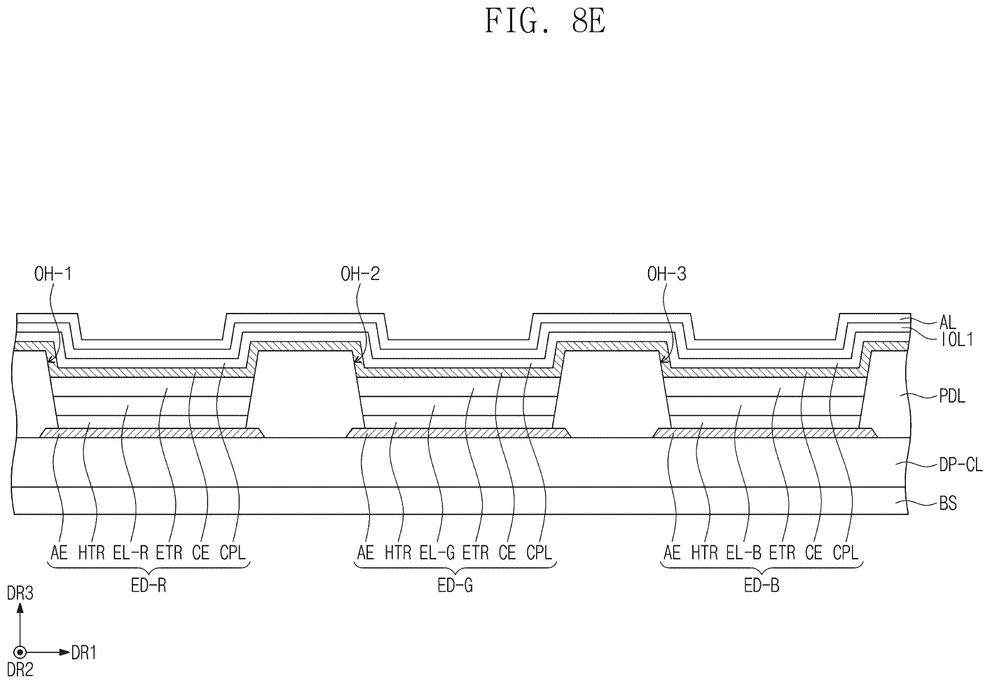

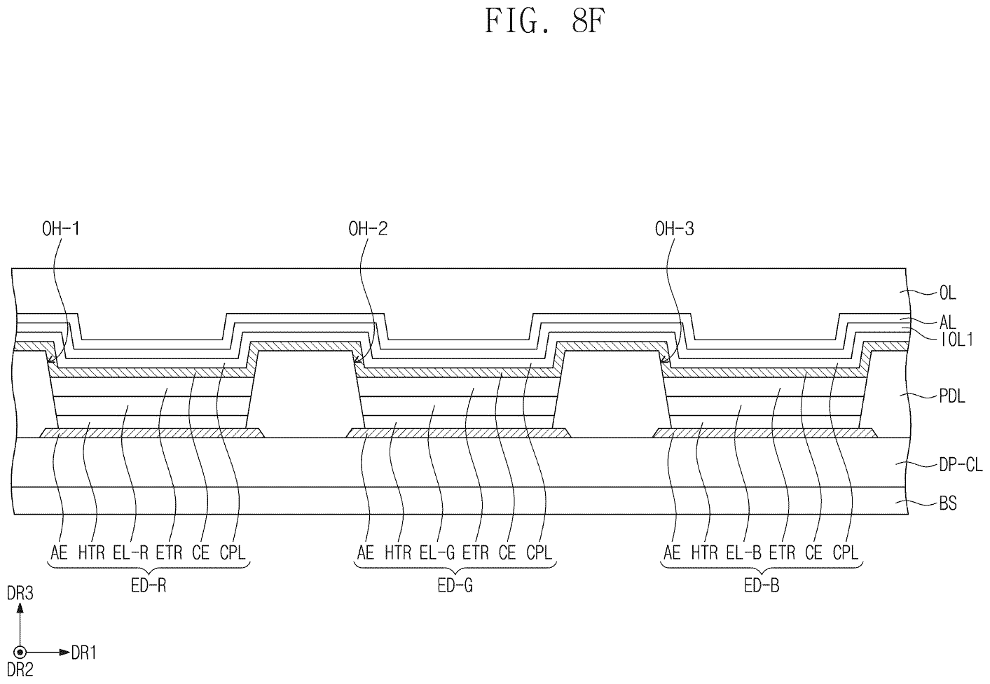

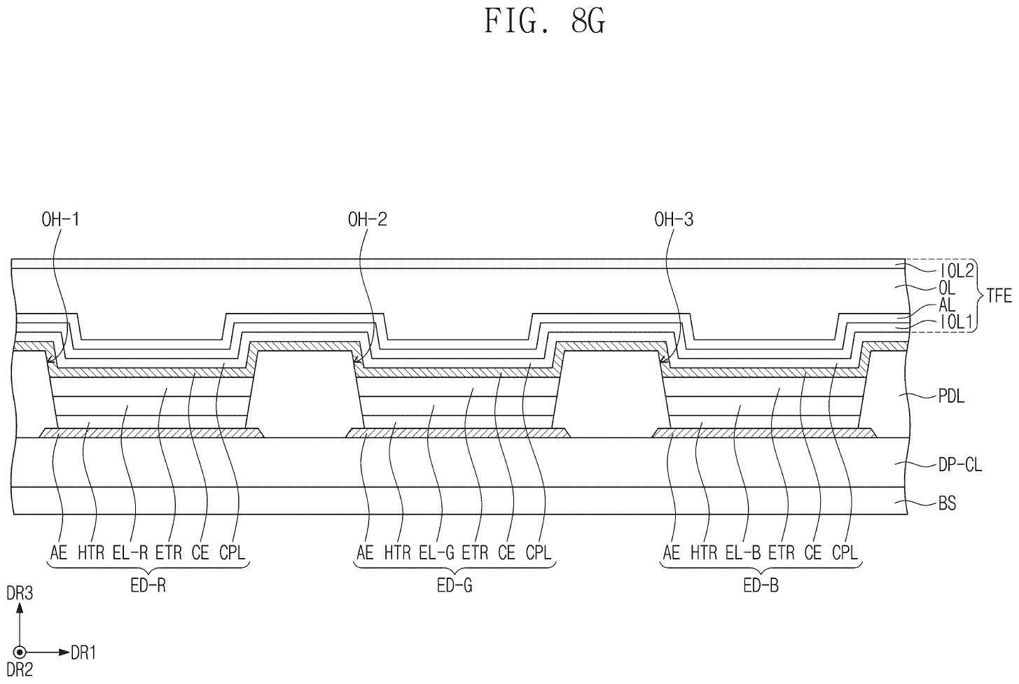

FIGS. 8A to 8G are cross-sectional views illustrating some steps (e.g., acts or tasks) of the method for manufacturing a display device according to one or more embodiments of the present disclosure. FIGS. 8A to 8G are cross-sectional views illustrating a process for forming the encapsulation layer TFE of one or more embodiments. The display device manufactured by the method for manufacturing a display device according to the embodiment described with reference to FIGS. 8A to 8G may have the structure of the display device of the embodiment described with reference to FIGS. 1 to 6B. Therefore, hereinafter, in describing the method for manufacturing a display device according to one or more embodiments of the present disclosure with reference to FIGS. 8A to 8G, the same reference numerals will be assigned to the same components as those of the display devices of FIGS. 1 to 6B described herein, and duplicated descriptions will not be provided.

Referring to FIG. 8A, the method for manufacturing a display device according to one or more embodiments of the present disclosure may include preparing light emitting elements ED-R, ED-G, and ED-B.

Referring to FIG. 8A, the light emitting elements ED-R, ED-G, and ED-B may be formed on the circuit layer DP-CL. The light emitting elements ED-R, ED-G, and ED-B may be provided and provided in the pixel openings OH-1, OH-2, and OH-3, respectively, defined in the pixel defining film PDL. The first light emitting element ED-R may be provided in the first pixel opening OH-1, the second light emitting element ED-G may be provided in the second pixel opening OH-2, and the third light emitting element ED-B may be provided in the third pixel opening OH-3. The pixel openings OH-1, OH-2, and OH-3 may be a portion corresponding to the first to third light emitting regions PXA-R, PXA-G, and PXA-B, respectively, described with reference to FIG. 5A and/or the like.

The preparing of the light emitting elements ED-R, ED-G, and ED-B may include forming the first electrode AE on the circuit layer DP-CL, forming the hole transport region HTR on the first electrode AE, forming the emission layers EL-R, EL-G, and EL-B on the hole transport region HTR, forming the electron transport region ETR on the emission layers EL-R, EL-G, and EL-B, and forming the second electrode CE on the electron transport region ETR.

The providing of the light emitting elements ED-R, ED-G, and ED-B may be performed through an inkjet process. In one or more embodiments, the light emitting elements ED-R, ED-G, and ED-B may include the hole transport region HTR, the emission layers EL-R, EL-G, and EL-B, and the electron transport region ETR, and at least one of the hole transport region HTR, the light emitting layers EL-R, EL-G, and EL-B, or the electron transport region ETR may be formed through the inkjet process. For example, the emission layers EL-R, EL-G, and EL-B among the hole transport region HTR, the emission layers EL-R, EL-G, and EL-B, and the electron transport region ETR may be formed through the inkjet process. In some embodiments, the hole transport region HTR, the emission layers EL-R, EL-G, and EL-B, and the electron transport region ETR may all be formed through the inkjet process.

The preparing of the light emitting elements ED-R, ED-G, and ED-B in the method for manufacturing a display device according to one or more embodiments of the present disclosure may further include forming an optical layer CPL. The optical layer CPL may be formed on the light emitting elements ED-R, ED-G, and ED-B. The optical layer CPL may be formed on the second electrode CE. The optical layer CPL may be formed by utilizing one or more suitable methods such as a vacuum deposition method, a spin coating method, a casting method, a Langmuir-Blodgett (LB) method, an inject printing method, a laser printing method, and a laser induced thermal imaging (LITI) method.

Referring to FIG. 8B, the method for manufacturing a display device according to one or more embodiments of the present disclosure may include forming a first inorganic encapsulation layer IOL1 on the light emitting elements ED-R, ED-G, and ED-B.

The first inorganic encapsulation layer IOL1 may be formed on the light emitting elements ED-R, ED-G, and ED-B. The forming of the first inorganic encapsulation layer IOL1 may be performed by a deposition process. The first inorganic encapsulation layer IOL1 may be formed by providing an inorganic material on the light emitting elements ED-R, ED-G, and ED-B through a deposition process. The inorganic material forming the first inorganic encapsulation layer IOL1 may include at least one of silicon nitride, silicon oxynitride, silicon oxide, titanium oxide, or aluminum oxide.

Referring to FIGS. 8C to 8E, a method for manufacturing a display device according to one or more embodiments of the present disclosure may include forming a polymer layer AL on the first inorganic encapsulation layer IOL1. The forming of the polymer layer AL of one or more embodiments may include applying a coating solution IK-A onto the first inorganic encapsulation layer IOL1 to form a preliminary polymer layer P-AL, and drying or heat-treating the preliminary polymer layer P-AL at a first temperature to form the polymer layer AL.

Referring to FIG. 8C, the preliminary polymer layer P-AL may be formed by applying the coating solution IK-A containing a first base resin and an organic acid derivative on the first inorganic encapsulation layer IOL1. The coating solution IK-A may be formed by applying through a suitable coating method such as spin coating, slit coating, or inkjet printing. For example, as illustrated in FIG. 8C, the coating solution IK-A including a first base resin and an organic acid derivative may be provided on the first inorganic encapsulation layer IOL1. The coating solution IK-A may be provided through a nozzle NZ. The coating solution IK-A may be entirely provided on the pixel openings OH-1, OH-2, and OH-3 and the pixel defining film PDL.

Referring to FIGS. 8D and 8E, the preliminary polymer layer P-AL may be dried or heat-treated at a first temperature to form the polymer layer AL (FIG. 8E). The solvent remaining in the preliminary polymer layer P-AL may be removed through the drying or heat-treating of the preliminary polymer layer P-AL. In one or more embodiments, the first temperature is not particularly limited, but for example, the first temperature may be about 25° C. to about 200° C. As illustrated in FIG. 8D, the polymer layer AL may be formed through the heat-treating of the preliminary polymer layer P-AL by applying heat h thereto.

The polymer layer AL may be formed to have a substantially constant thickness on the light emitting elements ED-R, ED-G, and ED-B and the pixel defining film PDL. The polymer layer AL may have a constant thickness along the top surface of the first inorganic encapsulation layer IOL1. For example, the polymer layer AL may be formed to overlap the first to third light emitting regions PXA-R, PXA-G, and PXA-B and the peripheral region NPXA and to have a substantially constant thickness in the first to third light emitting regions PXA-R, PXA-G, and PXA-B and the peripheral region NPXA. The polymer layer AL may be provided to follow a stepped portion on the top surface of the first inorganic encapsulation layer IOL1. As the light emitting elements ED-R, ED-G, and ED-B and the optical layer CPL are provided in the pixel openings OH-1, OH-2, and OH-3, a stepped portion may be formed on the top surface of the first inorganic encapsulation layer IOL1. The polymer layer AL may be provided to follow a stepped portion on the top surface of the first inorganic encapsulation layer IOL1, and a stepped portion may also be formed on the top surface of the polymer layer AL.

Referring to FIG. 8F, the method for manufacturing a display device according to one or more embodiments of the present disclosure may include forming an organic encapsulation layer OL on a polymer layer AL. The organic encapsulation layer OL may be formed by utilizing one or more suitable methods such as a vacuum deposition method, a spin coating method, a casting method, a Langmuir-Blodgett (LB) method, an inject printing method, a laser printing method, and a laser induced thermal imaging (LITI) method.

In one or more embodiments, the organic encapsulation layer OL may be formed by applying a second base resin on the polymer layer AL and then curing the second base resin. For example, the second base resin may be provided on the polymer layer AL to form a preliminary organic encapsulation layer. The second base resin forming the organic encapsulation layer OL may include at least one of an epoxy resin, a phenolic resin, or an acrylic resin. Thereafter, the preliminary organic encapsulation layer may be thermally cured or photocured to form the organic encapsulation layer OL. In one or more embodiments, the organic encapsulation layer may be formed by photocuring the preliminary organic encapsulation layer.

The organic encapsulation layer OL may have a flat top surface. The organic encapsulation layer OL may reduce a stepped portion of the polymer layer AL. The organic encapsulation layer OL may be provided to reduce the stepped portion of the top surface of the polymer layer AL so that the functional layer to be provided thereon may be uniformly provided. In one or more embodiments, the thickness of the organic encapsulation layer OL may be greater than the thickness of the polymer layer AL.

Referring to FIG. 8G, the method for manufacturing a display device according to one or more embodiments of the present disclosure may include forming a second inorganic encapsulation layer IOL2 on the organic encapsulation layer OL.

The second inorganic encapsulation layer IOL2 may be formed on the organic encapsulation layer OL. The forming of the second inorganic encapsulation layer IOL2 may be performed by a deposition process. The second inorganic encapsulation layer IOL2 may be formed by providing an inorganic material on the organic encapsulation layer OL through a deposition process. The inorganic material forming the second inorganic encapsulation layer IOL2 may include at least one of silicon nitride, silicon oxynitride, silicon oxide, titanium oxide, or aluminum oxide. The encapsulation layer TFE may be formed on the light emitting elements ED-R, ED-G, and ED-B through the forming of the second inorganic encapsulation layer IOL2. The preceding description in FIG. 5A and/or the like may be equally applied to the encapsulation layer TFE.

In some embodiments, in the herein-described method for manufacturing a display panel of FIGS. 8A to 8G, the display devices DD and DD-1 including the light emitting elements ED-R, ED-G, and ED-B having the stacked structure illustrated in FIGS. 5A and 6A are illustrated as examples, but the embodiment of the present disclosure is not limited thereto, and the display panels DD-a and DD-1a including the light emitting elements ED-R, ED-G, and ED-B having the stacked structure illustrated in FIGS. 5B and 6B may also be formed in substantially the same manner as the method for forming a display panel as described herein. For example, the method for manufacturing the display devices DD-a and DD-1a illustrated in FIGS. 5B and 6B may include sequentially providing the first electrode AE, the electron transport region ETR, the emission layers EL-R, EL-G, and EL-B, the hole transport region HTR, the second electrode CE, and the optical layer CPL to form the light emitting elements ED-R, ED-G, and ED-B, and forming the encapsulation layer TFE on the light emitting elements ED-R, ED-G, and ED-B. Here, the descriptions in FIGS. 8A and 8G may be equally applied to the forming of the encapsulation layer TFE.

The method for manufacturing a display device of one or more embodiments includes forming a polymer layer including an organic acid derivative between the organic encapsulation layer and the inorganic encapsulation layer adjacent to the light emitting element in the forming of the encapsulation layer, thereby improving current injection characteristics and luminous efficiency characteristics of the light emitting element including quantum dots, and thus providing the display device having excellent or suitable display efficiency.

In some embodiments, in the method for manufacturing a display device according to one or more embodiments of the present disclosure, the polymer layer is formed by directly providing a coating solution on the first inorganic encapsulation layer, thereby reducing a defect rate compared with a pressure attachment process. Accordingly, process efficiency and process reliability of the display device may be improved. In order to form a polymer layer on the display layer, a process of applying a coating solution onto a surface (e.g., one surface) of the encapsulation substrate and then pressing and bonding the encapsulation substrate and the display layer may be utilized. However, in this method, because the encapsulation substrate and the display layer are compressed at a pressure equal to or higher than a set or predetermined pressure, the coating solution may penetrate between the interfaces of the functional layers included in the display layer, thereby causing defects. In particular, when a coating solution containing an organic acid derivative exhibiting weak acidity is in contact with the electrode film, corrosion of the electrode film may be caused. According to the present disclosure, the first inorganic encapsulation layer is formed on the display layer, and a coating solution for forming the polymer layer is directly applied on the first inorganic encapsulation layer, and thus a pressing process and/or the like may not be provided. Accordingly, defects due to the penetration of the coating solution into the interface during a compression process of the display layer and the encapsulation substrate may be prevented or reduced, thereby improving process reliability and process efficiency of the display device.

In the display device of one or more embodiments, the encapsulation layer provided on the light emitting element includes the polymer layer including an organic acid derivative, so that the current efficiency characteristics and/or luminous efficiency of the light emitting element may be improved.

The method for manufacturing a display device of one or more embodiments may have improved reliability because the encapsulation layer capable of improving the current efficiency characteristics and/or luminous efficiency of the light emitting element may be formed.

Terms such as “substantially,” “about,” and “approximately” are used as relative terms and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or +30%, 20%, 10%, 5% of the stated value.

Numerical ranges disclosed herein include and are intended to disclose all subsumed sub-ranges of the same numerical precision. For example, a range of “1.0 to 10.0” includes all subranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

The display device, light emitting element, and/or any other relevant devices or components according to embodiments of the present disclosure described herein may be implemented utilizing any suitable hardware, firmware (e.g., an application-specific integrated circuit), software, or a combination of software, firmware, and hardware. For example, the various components of the light emitting device and/or light emitting element may be formed on one integrated circuit (IC) chip or on separate IC chips. Further, the various components of the light emitting device and/or light emitting element may be implemented on a flexible printed circuit film, a tape carrier package (TCP), a printed circuit board (PCB), or formed on one substrate. Further, the various components of the device and/or element may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the present disclosure has been described with reference to a preferred embodiment of the present disclosure, it will be understood that the present disclosure should not be limited to these preferred embodiments but one or more suitable changes and modifications can be made by those skilled in the art without departing from the spirit and scope of the present disclosure.

Accordingly, the technical scope of the present disclosure is not intended to be limited to the contents set forth in the detailed description of the specification, but is intended to be defined by the appended claims, and equivalents thereof.

What is claimed is:

1. A display device comprising:
a base layer comprising a pixel region and a peripheral region adjacent to the pixel region;
a pixel defining film on the base layer and comprising a light emitting opening corresponding to the pixel region;
a light emitting element in the light emitting opening and to generate a first color light; and
an encapsulation layer on the light emitting element,
the encapsulation layer comprising:
a first inorganic encapsulation layer on the light emitting element;
a polymer layer on the first inorganic encapsulation layer and comprising a base resin and an organic acid derivative;
an organic encapsulation layer on the polymer layer; and
a second inorganic encapsulation layer on the organic encapsulation layer.

2. The display device of claim 1, wherein the base resin comprises at least one of polyacrylic acid, polymethyl methacrylate, polystyrene, or polyvinyl pyrrolidone.

3. The display device of claim 1, wherein the organic acid derivative comprises a carboxylic acid compound or a carboxylic acid ester compound.

4. The display device of claim 1, wherein the organic acid derivative comprises at least one of citric acid, methacrylic acid, acrylic acid, isobutyric acid, alkyl (meth)acrylate, or hydroxyalkyl (meth)acrylate.

5. The display device of claim 1, wherein the polymer layer has a thickness of about 100 nanometer (nm) to about 1,000 nm.

6. The display device of claim 1, wherein an amount of the organic acid derivative is about 2 wt % to about 50 wt % with respect to a total amount of the polymer layer.

7. The display device of claim 1, wherein the polymer layer is on the pixel region and the peripheral region and has a set thickness.

8. The display device of claim 1, wherein the polymer layer is directly on the first inorganic encapsulation layer,
the organic encapsulation layer is directly on the polymer layer, and
the second inorganic encapsulation layer is directly on the organic encapsulation layer.

9. The display device of claim 1, wherein the light emitting element comprises a first electrode, a second electrode, and an emission layer between the first electrode and the second electrode and being to emit the first color light, and
the first color light is to be emitted from the first electrode to the second electrode.

10. The display device of claim 9, wherein the light emitting element further comprises:
a hole transport region between the first electrode and the emission layer; and
an electron transport region between the second electrode and the emission layer.

11. The display device of claim 9, wherein the light emitting element further comprises:
an electron transport region between the first electrode and the emission layer; and
a hole transport region between the second electrode and the emission layer.

12. The display device of claim 9, wherein the emission layer comprises quantum dots.

13. The display device of claim 9, further comprising an optical layer between the second electrode and the encapsulation layer.

14. The display device of claim 1, further comprising a color filter layer on the encapsulation layer,
the color filter layer comprising:
a first filter configured to transmit the first color light;
a second filter configured to transmit a second color light having a wavelength region greater than a wavelength region of the first color light; and
a third filter configured to transmit a third color light having a wavelength region greater than the wavelength region of the second color light.

15. The display device of claim 14, further comprising a buffer layer between the encapsulation layer and the first to third filters,
the encapsulation layer being covered by the buffer layer.

16. The display device of claim 14, wherein the color filter layer is directly on the encapsulation layer.

17. The display device of claim 14, wherein the color filter layer further comprises light shielding parts between a neighboring pair selected from among the first filter, the second filter, and the third filter, and
the second inorganic encapsulation layer is directly on a surface of each of the first filter, the second filter, the third filter, and the light shielding parts.

18. A method for manufacturing a display device, the method comprising:
preparing a light emitting element;
forming a first inorganic encapsulation layer on the light emitting element;
applying a coating solution containing a first base resin and an organic acid derivative on the first inorganic encapsulation layer to form a preliminary polymer layer;
drying or heat-treating the preliminary polymer layer at a first temperature to form a polymer layer;
forming an organic encapsulation layer on the polymer layer; and
forming a second inorganic encapsulation layer on the organic encapsulation layer.

19. The method of claim 18, wherein the first temperature is about 25° C. to about 200° C.

20. The method of claim 18, wherein the forming of the organic encapsulation layer comprises applying and curing a second base resin on the polymer layer.
